(19) United States
(12) Patent Application Publication
(10) Pub. No.: US 2025/0155474 A1
(43) Pub. Date: May 15, 2025

(54) METHOD FOR MANUFACTURING CURRENT SENSOR

(71) Applicant: DENSO CORPORATION, Kariya-city (JP)

(72) Inventors: Kazuhiro YOSHINO, Kariya-city (JP); Takeshi TSUKAMOTO, Kariya-city (JP); Akito SASAKI, Kariya-city (JP)

(21) Appl. No.: 19/024,901

(22) Filed: Jan. 16, 2025

Related U.S. Application Data
(63) Continuation of application No. PCT/JP2022/028326, filed on Jul. 21, 2022.

(51) Int. Cl. G01R 3/00; G01R 15/20; H05K 9/00

(52) U.S. Cl. CPC G01R 3/00; H05K 9/0028; G01R 15/207

(57) ABSTRACT

In a method for manufacturing a current sensor, a wiring board is placed by bringing the wiring board into contact with board contact portions of a sensor housing while deforming an adhesive applied on top surfaces of board adhesion portions of the sensor housing between the board adhesion portions and the wiring board, and a shield is placed by bringing the shield into contact with shield contact portions of the sensor housing while deforming an adhesive applied on top surfaces of shield adhesion portions of the sensor housing between the shield adhesion portions and the shield. After the placing of the wiring board and the placing of the shield, both the adhesive positioned between the board adhesion portions and the wiring board and the adhesive positioned between the shield adhesion portions and the shield are cured simultaneously.

### CROSS REFERENCE TO RELATED APPLICATIONS

The present application is a continuation application of International Patent Application No. PCT/JP2022/028326 filed on Jul. 21, 2022, which designated the U.S. and the entire disclosures of the above application are incorporated herein by reference.

### TECHNICAL FIELD

The present disclosure relates to a method for manufacturing a current sensor.

### BACKGROUND

For example, JP 6919609 B2 discloses a current sensor. The current sensor has a wiring board on which a magnetoelectric conversion unit is mounted. Furthermore, the current sensor has a plate-shaped magnetic shield for suppressing magnetic noise components. The current sensor has the wiring board and the shield within a sensor housing. The contents of JP 6919609 B2 are incorporated herein by reference as explanations of the technical elements in this specification.

### SUMMARY

The present disclosure describes a method for manufacturing a current sensor. According to an aspect, the method includes: preparing a sensor housing, a wiring board and a shield; placing the wiring board by bringing the wiring board into contact with a plurality of board contact portions of the sensor housing while deforming an adhesive applied on a plurality of top surfaces of board adhesion portions of the sensor housing between the top surfaces of the board adhesion portions and the wiring board; placing the shield by bringing the shield into contact with a plurality of shield contact portions of the sensor housing while deforming an adhesive applied on a plurality of top surfaces of shield adhesion portions of the sensor housing between the top surfaces of the shield adhesion portions and the shield; and after the placing of the wiring board and the placing of the shield, curing both the adhesive positioned between the board adhesion portions and the wiring board and the adhesive positioned between the shield adhesion portions and the shield simultaneously.

### BRIEF DESCRIPTION OF DRAWINGS

Features and advantages of the present disclosure will become more apparent from the following detailed description made with reference to the accompanying drawings, in which:

FIG. 1 is a perspective view of a current sensor according to a first embodiment;

FIG. 2 is an exploded perspective view of the current sensor;

FIG. 3 is a plan view of the current sensor when viewed along an arrow III in FIG. 2;

FIG. 4 is a plan view of a wiring board;

FIG. 5 is a plan view of a first shield;

FIG. 6 is a plan view when viewed along an arrow VI in FIG. 2;

FIG. 7 is a plan view when viewed along an arrow VII in FIG. 2;

FIG. 8 is a plan view when viewed along an arrow VIII in FIG. 2;

FIG. 9 is a cross-sectional view taken along line IX-IX in FIG. 8;

FIG. 10 is a modeled cross-sectional view showing an adhered state;

FIG. 11 is a perspective view of a cover;

FIG. 12 is a back side view of the cover;

FIG. 13 is a cross-sectional view of a current sensor;

FIG. 14 is a side view of a magnetic shield;

FIG. 15 is a perspective view of the magnetic shield;

FIG. 16 is an exploded perspective view of the shield;

FIG. 17 is a flow chart showing a procedure in a manufacturing process of the current sensor;

FIG. 18 is a block diagram of an application device in an applying step;

FIG. 19 is a plan view of a wiring board;

FIG. 20 is a block diagram explaining a sensing unit;

FIG. 21 is a plan view of a current sensor according to a second embodiment;

FIG. 22 is a cross-sectional view showing an assembling state of the current sensor; and

FIG. 23 is a perspective view of a magnetic shield according to a third embodiment.

### DETAILED DESCRIPTION

In the technique disclosed in JP 6919609 B2, after a wiring board is adhered to a sensor housing, a shield is bonded to the sensor housing. Current sensors are required to have a high degree of productivity suitable for mass production. From another viewpoint, high accuracy in terms of detection performance is required for the current sensor. For these reasons, high accuracy is required for the positional relationships of the wiring board and the shield relative to the bus bar. In the above respects, and in other respects not mentioned, further improvements are desired in current sensors and methods for manufacturing current sensors.

The present disclosure provides a method for manufacturing a current sensor that can realize a high degree of productivity suitable for mass production.

According to an aspect of the present disclosure, a method for manufacturing a current sensor includes: preparing a sensor housing that holds a conductive member for allowing an electric current to flow and that includes a plurality of board contact portions, a plurality of board adhesion portions, a plurality of shield contact portions, and a plurality of shield adhesion portions, a wiring board that has a sensor element mounted thereon for detecting a magnetic flux caused by the electric current, and a shield as a magnetic shield member; placing the wiring board by bringing the wiring board into contact with the plurality of board contact portions so that the wiring board is placed in a specified position and bringing the wiring board into contact with an adhesive applied on a plurality of top surfaces of the board adhesion portions so that the adhesive is deformed between the top surfaces of the board adhesion portions and the wiring board; placing the shield by bringing the shield into contact with the plurality of shield contact portions so that the shield is placed in a specified position and deforming an adhesive applied on a plurality of top surfaces of the shield adhesion portions between the top surfaces of the shield adhesion portions and the shield; and after the placing of the wiring board and the placing of the shield, simultaneously curing both the adhesive positioned between the board adhesion portions and the wiring board and the adhesive positioned between the shield adhesion portions and the shield.

The present disclosure provides a method for manufacturing a current sensor. In the method for manufacturing the current sensor, the wiring board is brough into contact with the adhesive applied on the top surfaces of the plurality of board adhesion portions, thereby deforming the adhesive between the top surfaces and the wiring board. As a result, the wiring board is positioned to the specified position. Moreover, the board adhesive is deformed into a shape suitable for the specified position. In the method for manufacturing the current sensor, the shield is brought into contact with the adhesive applied on the top surfaces of the plurality of shield adhesion portions, thereby deforming the adhesive between the top surfaces and the shield. As a result, the shield is positioned to the specified position. Moreover, the adhesive is deformed into a shape suitable for the specified position. In the curing performed after the placing of the wiring board and the placing of the shield, the adhesive on the board adhesion portions and the adhesive on the shied adhesion portions are cured simultaneously. In the curing, both the adhesive positioned between the board adhesion portions and the wiring board and the adhesive positioned between the shield adhesion portions and the shield are cured at the same time. As a result, a high degree of productivity suitable for mass production is realized.

Various embodiments disclosed in this specification employ different technical means to achieve their respective objectives.

Hereinafter, various embodiments will be described with reference to the drawings. In several embodiments, functionally and/or structurally corresponding and/or related parts may be given the same reference numerals or reference numerals that differ in the hundredth or higher digits. For corresponding and/or related parts, reference may be made to the descriptions of other embodiments.

Regarding the current sensor 1, reference can be made to the description of JP 6919609 B2, which is disclosed as a patent document. The contents of JP 6919609 B2 are incorporated herein by reference as an explanation of the technical elements in this specification.

### First Embodiment

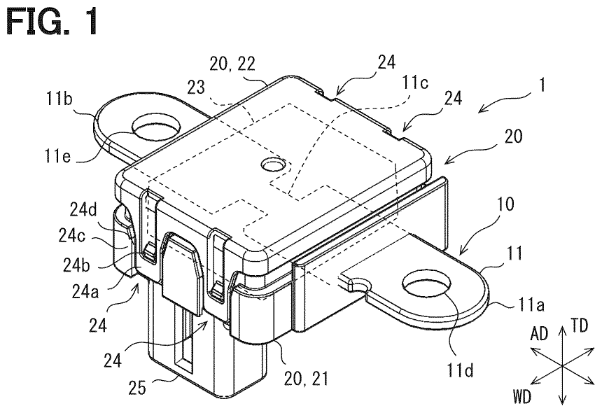

A current sensor 1 is shown in FIG. 1. In the following description, the current sensor 1 will be described assuming a three-axis orthogonal coordinate system. The direction in which a current, as a detection target, flows in the current sensor 1 is referred to as an axial direction AD. The axial direction AD indicates the direction of the current to be detected. In the illustrated example, the axial direction AD indicates the main current direction in a narrowed portion 11c, which will be described later. A direction perpendicular to the axial direction AD and parallel to the planar direction of a conductor member 11, which will be described later, is referred to as a width direction WD. A direction perpendicular to the axial direction AD and the width direction WD is referred to as a thickness direction TD. The thickness direction TD is also an opposing direction between the narrowed portion 11c and a sensor element 42, which will be described later. The width direction WD may also be referred to as the X direction, the axial direction AD may also be referred to as the Y direction, and the thickness direction TD may also be referred to as the Z direction.

In FIG. 1, the current sensor 1 is used to detect a current in a control unit for a battery and/or a control unit for a rotating electrical machine. The current may range from a few amperes to hundreds of amperes. The current sensor 1 is designed with heat dissipation properties and materials so as to withstand high temperatures caused by heat generation and maintain its functionality. The battery and/or the rotating electric machines is used to provide power for stationary or mobile object. The stationary object is used in a variety of applications, such as air conditioning device, a water pumping device, and a winding device. The mobile object is used in a variety of applications such as a vehicle, a ship, and an aircraft. The mobile object includes a human vehicle and an unmanned mobile body that is not intended for humans to ride on. The battery and/or the rotating electric machine can be used as a power source for moving the mobile object. For example, the rotating electric machine may be connected to a drive wheel of a vehicle so as to allow bidirectional or unidirectional power transmission. For example, the rotating electric machine may be connected to a propeller of a ship or an aircraft so as to allow bidirectional or unidirectional power transmission. The battery and/or rotating electric machine may be utilized in a variety of accessories such as windshield wipers, compressors, automatic doors, and the like. In the present embodiment, the current sensor 1 is used in a battery control ECU for controlling the charging current and/or discharging current of the battery. Alternatively, the current sensor 1 may be used in a power conversion device that controls the power running operation and/or the regenerative operation of the rotating electric machine. The current sensor 1 may be used to detect input/output currents in a converter circuit and/or an inverter circuit in the power conversion device.

The current sensor 1 includes a conductive member 10 that allows an electric current to flow. The conductive member 10 may be provided by a bus bar made of a metal plate, or by a single-core or multi-core wire. In the present embodiment, the conductive member 10 includes a conductor member 11 as a bus bar. The conductor member 11 is a member that can be called as a strip-shaped or plate-shaped member. The longitudinal direction of the conductor member 11 corresponds to the direction in which current flows, that is, the axial direction AD. The conductor member 11 has the thickness direction TD along its thickness. The conductor member 11 has a width direction WD along its lateral or width. The conductor member 11 is a member made of a metal such as copper or aluminum.

The conductor member 11 has connection portions for connecting to circuit components at both ends in the axial direction AD. One end 11a of the conductor member 11 is provided with a through hole 11d (bolt hole) for receiving a bolt as a shaft of a connecting mechanism. The through hole 11d is a circular hole that penetrates the conductor member 11. The other end 11b of the conductor member 11 is provided with a through hole 11e for receiving a bolt as a shaft of the connecting mechanism. The through hole 11e is a circular hole that penetrates the conductor member 11. The diameter of the through hole 11d is equal to the diameter of the through hole 11e. Each of the through holes 11d and 11e may be provided by a cutout having an opening at the edge, which may be called a U-shape or a C-shape.

The conductor member 11 has the narrowed portion 11c at a detection position. The width of the conductor member 11 is partially narrowed at the narrowed portion 11c in the width direction WD. The narrowed portion 11c concentrates the current to be detected. A sensor element, which will be described later, is disposed at a position spaced a predetermined small distance from the narrowed portion 11c in the thickness direction TD.

The current sensor 1 includes an insulating member 20. The insulating member 20 is made of an electrically insulating material. The insulating member 20 is made of, for example, an electrically insulating resin material. The insulating member 20 may be made of, for example, ceramics. The insulating member 20 provides a fixing member for fixing the conductive member 10. The insulating member 20 provides a container chamber 23 for housing electrical circuit components constituting the current sensor 1. The insulating member 20 provides a connector 25 that provides an electrical connection for the current sensor 1. Additionally, the insulating member 20 provides a fixing member for fixing a magnetic shielding member. The insulating member 20 includes a sensor housing 21 and a cover 22. The sensor housing 21 is a member that is also referred to as a main body or a body of the current sensor 1. The sensor housing 21 is a main component that forms the container chamber 23. The cover 22 is a member that covers the opening of the container chamber 23.

The conductive member 10 is inserted in the sensor housing 21 to be fixed in the sensor housing 21. The sensor housing 21 fixes the conductive member 10 so that the one end 11a and the other end 11b are exposed. The sensor housing 21 and the cover 22 define the container chamber 23 therebetween for housing the electric circuit components constituting the current sensor 1. therein The container chamber 23 is a slightly flattened rectangular chamber. The sensor housing 21 and the cover 22 secure a shield member. A portion of the shield member is housed within the container chamber 23. The remainder of the shield member is fixed to an outer surface of the sensor housing 21.

The sensor housing 21 and the cover 22 include a plurality of coupling mechanisms 24. The sensor housing 21 and the cover 22 are coupled by the coupling mechanisms 24. The plurality of coupling mechanisms 24 are disposed in a dispersed manner in the width direction WD of the insulating member 20. In the illustrated example, two coupling mechanisms 24 are disposed on one side of the insulating member 20 in the width direction WD. Two coupling mechanisms 24 are disposed on the other side of the insulating member 20 in the width direction WD. The coupling mechanism 24 is a reversible coupling mechanism that can transition between a coupled state and a separated state in both directions. The coupled state is shown in the drawing. The coupling mechanism 24 utilizes elastic deformation of the material that constitutes the cover 22. The coupling mechanism 24 is also referred to as a snap-fit mechanism that utilizes the elastic deformation of the member.

The coupling mechanism 24 includes an engagement arm 24a having a movable claw, and a fixed engagement claw 24b. The engagement arm 24a extends from the cover 22 toward the sensor housing 21 in the thickness direction TD. The engagement claw 24b protrudes in the width direction WD from a side surface of the sensor housing 21 facing the width direction WD. The engagement arm 24a is elastically deformable so that the tip portion extending from the cover 22 moves in the width direction WD. In the separated state, the engagement arm 24a is in a natural state with no elastic deformation. In the process of assembling the cover 22 to the sensor housing 21, the engagement arm 24a is elastically deformed by mechanical interference between the engagement arm 24a and the engagement claw 24b. The amount of elastic deformation of the engagement arm 24a enables mechanical engagement between the engagement arm 24a and the engagement claw 24b. The engagement arm 24a is deformable to receive the engagement claw 24b. When the relative positions of the engagement arm 24a and the engagement claw 24b reach the engaged position, the engagement arm 24a returns to its natural state due to elastic force. In this engaged position, the engagement claw 24b restrains the engagement arm 24a. As a result, the sensor housing 21 and the cover 22 are coupled and fixed. At this time, the container chamber 23 is sealed by the sensor housing 21 and the cover 22.

Furthermore, the sensor housing 21 has a side wall surface 24c that protrudes higher in the width direction WD than the engagement arm 24a in the engaged position. The side wall surface 24c defines a groove 24d for receiving the engagement arm 24a. The side wall surface 24c defines the groove 24d so as to surround the engagement claw 24b. In the coupled state, the groove 24d receives the engagement arm 24a. As a result, in the coupled state, the engagement arm 24a is disposed so as to be embedded inside the sensor housing 21 from the surface of the sensor housing 21. The dimension of the sensor housing 21 in the width direction WD is determined by the side wall surface 24c. The engagement arm 24a is positioned so as to be recessed from the side wall surface 24c. Therefore, the coupling mechanism 24 can be disposed without increasing the dimension of the sensor housing 21 in the width direction WD.

The sensor housing 21 provides a connector 25 that provides an electrical connection for the current sensor 1. The connector 25 is a tubular member with one open end. The connector 25 has electrical connection terminals therein. The opening of the connector 25 faces the thickness direction TD. The connector 25 is one of two connector parts that provide the electrical connection. The connector 25 is arranged so that it can be connected to or separated from the other connector part by relative movement in a direction perpendicular to the axial direction AD. In the illustrated example, the connection and separation direction of the connector 25 is the thickness direction TD. The orientation direction of the connector 25 is also the direction in which the bolts are received in the through holes 11d and 11e.

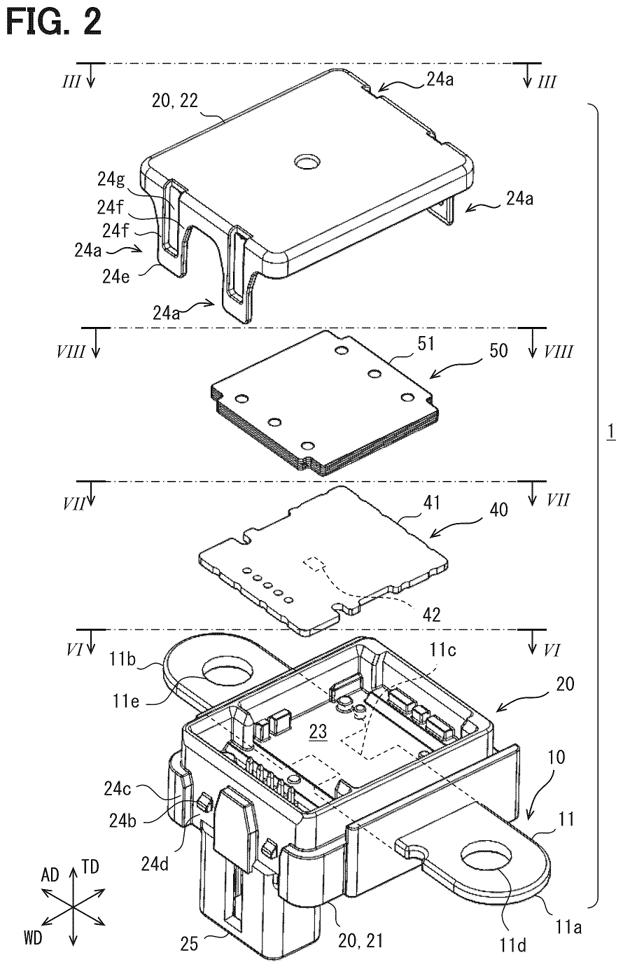

FIG. 2 is an exploded perspective view of the sensor housing 21, the cover 22, an electric circuit component 40, and a shield member 50. The container chamber 23 is defined between the sensor housing 21 and the cover 22. The bottom surface of the container chamber 23 has a wall surface made of the material of the sensor housing 21. The conductive member 10 is also embedded in the sensor housing 21 within the container chamber 23.

The cover 22, which is shown at the uppermost position in the figure, has four engagement arms 24a. The engagement arm 24a is provided with a movable engagement claw 24e which engages with the fixed engagement claw 24b. The engagement claw 24b is also referred to as a fixing claw or a protrusion. The engagement claw 24e is also referred to as a movable claw or a hook. The engagement arm 24a includes two elastic arms 24f extending in parallel from the cover 22 along the thickness direction TD. The engagement claw 24e is disposed so as to connect the tip portions of the two elastic arms 24f. A window portion 24g is defined between the two elastic arms 24f. The window portion 24g defines a slit shape that extends thinly in the thickness direction TD along the two elastic arms 24f. In the coupled state, the window portion 24g can receive the engagement claw 24b.

The sensor housing 21, which is shown at the lowermost position in the figure, has the side wall surface 24c that is raised around the engagement claw 24b so as to define a groove 24d around the engagement claw 24b. It can be expressed in an opposite manner. That is, the groove 24d is defined and formed by recessing the side wall surface 24c in the width direction WD. Furthermore, the engagement claw 24b is provided by protruding a part of the groove 24d.

In the figure, the coupling mechanism 24 is shown in the separated state. The process of assembling the insulating member 20 includes a step of bringing the sensor housing 21 and the cover 22 close to each other along the thickness direction TD. In this step, the sensor housing 21 and the cover 22 transition from the separated state to the coupled state. When the engagement arm 24a reaches the range of the groove 24d, the engagement arm 24a collides with the raised shape of the side wall surface 24c. As a result, the engagement arm 24a is guided along the groove 24d. Eventually, the engagement claw 24e of the engagement arm 24a reaches the engagement claw 24b.

When the engagement claw 24e collides with the engagement claw 24b, the engagement arm 24a gradually undergoes elastic deformation along the inclined surface of the engagement arm 24a or the engagement claw 24b. This elastic deformation is provided mainly by the deformation of the elastic arm 24f. Even during this process of elastic deformation, the engagement arm 24a is guided along the groove 24d. When the engagement claw 24e eventually passes over the engagement claw 24b, the engagement arm 24a is restored to its original shape by its elastic force. As a result, the engagement claw 24b is received in the window portion 24g. This completes the coupling between the engagement arm 24a and the engagement claw 24b.

In the present embodiment, the engagement arm 24a is guided along the groove 24d by the raised side wall surface 24c. Therefore, in assembling the insulating member 20, the sensor housing 21 and the cover 22 can be coupled reliably and easily. At the same time, the container chamber 23 can be sealed reliably and easily. The behavior of the coupling mechanism 24 in such an assembly process is carried out substantially simultaneously for all of the plurality of coupling mechanisms 24.

When the coupling mechanism 24 is in the coupled state, the engagement arm 24a is at least partially embedded in the groove 24d. In the illustrated example, the side wall surface 24c protrudes beyond the engagement arm 24a in the width direction WD. This provides a state in which the entire engagement arm 24a is embedded in the groove 24d. As a result, the coupling mechanism 24 is restricted from protruding on the outer surface of the insulating member 20. From another point of view, the engagement arm 24a is protected by the raised side wall surface 24c. As a result, the transition from the coupled state to the separated state due to the operation of the engagement arm 24a is suppressed.

A wiring board 41 as one member of the electric circuit component 40 is disposed in the container chamber 23. The electric circuit component 40 includes the wiring board 41 and components mounted on the wiring board 41. Circuit elements are arranged on the surface of the wiring board 41. In the figure, a sensor element 42 is illustrated. The sensor element 42 is disposed on the lower surface of the wiring board 41 in the figure. The sensor element 42 is disposed on the surface of the wiring board 41 facing the sensor housing 21. In other words, the sensor element 42 is disposed between the wiring board 41 and the conductive member 10. Although one sensor element 42 is illustrated in the figure, the sensor element 42 includes a plurality of sensing units 121 and 122 that constitute a multiplexed system capable of backing up each other. The sensor element 42 includes at least two magnetoelectric conversion units 125 that constitute a multiplexed system capable of backing up each other.

Regarding the sensor element 42 and the circuitry associated with the sensor element 42, the contents of JP 6919609 B2 can be incorporated herein by reference.

As shown in FIG. 19, the wiring board 41 has a flat plate shape. The wiring board 41 has a flat shape with a small thickness in the thickness direction TD. The wiring board 41 is formed by laminating a plurality of insulating resin layers and conductive metal layers in the thickness direction TD. An opposing surface 41c having the largest area of the wiring board 41 and a back surface on the back side thereof face in the thickness direction TD. FIG. 19 shows a bottom view of the wiring board 41, showing the surface on which circuit elements are mounted. The surface of the wiring board 41 shown in FIG. 19 is referred to as the opposing surface 41c. The opposite surface of the wiring board 41 is also referred to as the back surface.

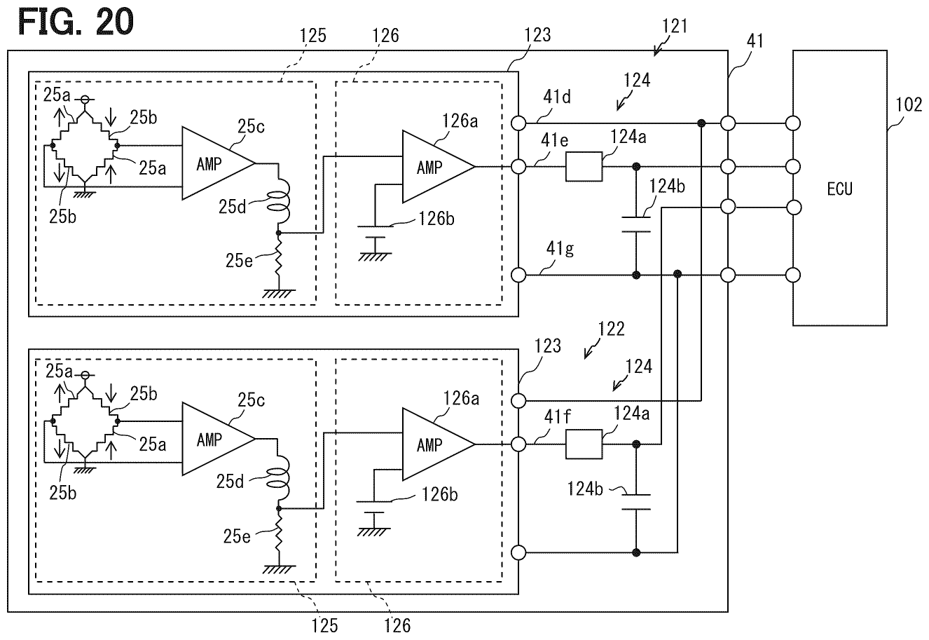

A first sensing unit 121 and a second sensing unit 122, shown in FIG. 19 and FIG. 20, are mounted on the opposing surface 41c of the wiring board 41. The first sensing unit 121 and the second sensing unit 122 provide the sensor element 42. The first sensing unit 121 includes an ASIC 123 and a filter 124. The second sensing unit 122 includes an ASIC 123 and a filter 124. The ASIC 123 and the filter 124 are electrically connected via a wiring pattern of the wiring board 41. A connection terminal of the connector 25 is electrically connected to this wiring pattern. ASIC stands for Application Specific Integrated Circuit. It is also possible to adopt a configuration in which the first sensing unit 121 and the second sensing unit 122 are mounted on the back surface. Both the first sensing unit 121 and the second sensing unit 122 have the same configuration as described below.

The ASIC 123 has a magnetoelectric conversion unit 125, a processing circuit 126, connection pins 127, and a resin part 128. The magnetoelectric conversion unit 125 and the processing circuit 126 are electrically connected to each other. A first end of each connection pin 127 is electrically connected to the processing circuit 126. A second end of each connection pin 127 is electrically and mechanically connected to the wiring board 41. The first ends of the connection pins 127, the processing circuit 126, and the magnetoelectric conversion unit 125 are covered with the resin part 128. The second end of the connection pin 127 is exposed from the resin part 128.

The magnetoelectric conversion unit 125 has a magnetoresistive element whose resistance value varies in response to the magnetic field that passes through it (transmission magnetic field). The magnetoelectric conversion unit 125 has a plurality of magnetoresistive elements. The resistance value of the magnetoresistive element changes in response to the transmission magnetic field along the opposing surface 41c. That is, the resistance value of the magnetoresistive element changes depending on the component of the transmission magnetic field along the width direction WD and the component along the axial direction AD.

On the other hand, the resistance value of the magnetoresistive element does not change due to a transmission magnetic field along the thickness direction TD. Therefore, even if external noise in the thickness direction TD passes through the magnetoresistive element, the resistance value of the magnetoresistive element does not change.

The magnetoresistive element has a pinned layer whose magnetization direction is fixed, a free layer whose magnetization direction changes in response to the transmission magnetic field, and a non-magnetic intermediate layer provided between the pinned layer and the free layer. When the intermediate layer is non-conductive, the magnetoresistive element is a giant magnetoresistive element. When the intermediate layer is conductive, the magnetoresistive element is a tunneling magnetoresistive element. The magnetoresistive element may be an anisotropic magnetoresistive element (AMR). Furthermore, the magnetoelectric conversion unit 125 may have a Hall element instead of the magnetoresistive element.

The resistance value of the magnetoresistive element changes depending on the angle between the magnetization directions of the pinned layer and free layer. The magnetization direction of the pinned layer is along the facing surface. The magnetization direction of the free layer is determined by the transmission magnetic field along the facing surface. The resistance value of the magnetoresistive element is smallest when the magnetization directions of the free layer and the fixed layer are parallel to each other. The resistance value of the magnetoresistive element is greatest when the magnetization directions of the free layer and the fixed layer are antiparallel to each other.

The magnetoelectric conversion unit 125 has a first magnetoresistive element 25a and a second magnetoresistive element 25b as the above-mentioned magnetoresistive elements. The magnetization directions of the pinned layers of the first magnetoresistive element 25a and the second magnetoresistive element 25b differ by 90°. Therefore, the increase and decrease in the resistance value of the first magnetoresistive element 25a and the second magnetoresistive element 25b are reversed. When the resistance value of one of the first magnetoresistive element 25a and the second magnetoresistive element 25b decreases, the resistance value of the other increases by an equivalent amount.

The magnetoelectric conversion unit 125 has two first magnetoresistive elements 25a and two second magnetoresistive elements 25b. The first magnetoresistive element 25a and the second magnetoresistive element 25b are connected in series in this order from the power supply potential toward the reference potential to form a first half-bridge circuit. The second magnetoresistive element 25b and the first magnetoresistive element 25a are connected in series in this order from the power supply potential toward the reference potential to form a second half-bridge circuit.

In this way, the arrangement of the first magnetoresistive element 25a and the second magnetoresistive element 25b is reversed between the two half-bridge circuits. For this reason, the midpoint potential of the two half-bridge circuits is configured such that when the potential of one drops, the potential of the other rises. In the magnetoelectric conversion unit 125, these two half-bridge circuits are combined to form a full-bridge circuit.

The magnetoelectric conversion unit 125 includes a differential amplifier 25c, a feedback coil 25d, and a shunt resistor 25e in addition to the magnetoresistive elements that configure the full-bridge circuit described above. The midpoint potentials of the two half-bridge circuits are input to the inverting input terminal and the non-inverting input terminal of the differential amplifier 25c. The feedback coil 25d and the shunt resistor 25e are connected in series from the output terminal of the differential amplifier 25c toward the reference potential.

With the above-described connection configuration, an output corresponding to the fluctuation in the resistance value of the first magnetoresistive elements 25a and the second magnetoresistive elements 25b that form the full-bridge circuit is output from the output terminal of the differential amplifier 25c. This change in resistance value occurs when a magnetic field passes through the magnetoresistance element along the facing surface. A magnetic field (magnetic field to be measured) generated by a current flowing through the conductive member 10 passes through the magnetoresistive element. Therefore, a current corresponding to the magnetic field to be measured flows through the input terminal of the differential amplifier 25c.

The input terminals and the output terminal of the differential amplifier 25c are connected via a feedback circuit (not shown). For this reason, the differential amplifier 25c is virtually shorted. Therefore, the differential amplifier 25c operates so that the inverting input terminal and the non-inverting input terminal have the same potential. That is, the differential amplifier 25c operates so that the current flowing through the input terminal and the current flowing through the output terminal become zero. As a result, the current (feedback current) corresponding to the magnetic field to be measured flows from the output terminal of the differential amplifier 25c.

The feedback current flows between the output terminal of the differential amplifier 25c and the reference potential through the feedback coil 25d and the shunt resistor 25e. This flow of feedback current generates a compensating magnetic field in the feedback coil 25d. This compensating magnetic field passes through the magnetoelectric conversion unit 125. This cancels out the magnetic field to be measured that passes through the magnetoelectric conversion unit 125. In this way, the magnetoelectric conversion unit 125 operates so that the magnetic field to be measured that passes through it and the compensating magnetic field are in balance.

A feedback voltage corresponding to the amount of feedback current that generates the compensating magnetic field is generated at the midpoint between the feedback coil 25d and the shunt resistor 25e. This feedback voltage is output to the downstream processing circuit 126 as an electrical signal that detects the current to be measured.

The processing circuit 126 includes an adjustment amplifier 126a and a threshold power supply 126b. The midpoint between the feedback coil 25d and the shunt resistor 25e is connected to a non-inverting input terminal of the adjustment amplifier 126a. A threshold power supply 126b is connected to an inverting input terminal of the adjustment amplifier 126a. As a result, a differentially amplified feedback voltage is output from the adjustment amplifier 126a.

The resistance value of each of the first magnetoresistive elements 25a and the second magnetoresistive elements 25b that configure the full bridge circuit has a property that depends on temperature. Therefore, the output of the adjustment amplifier 126a fluctuates with temperature changes. Therefore, the processing circuit 126 includes a temperature detection element (not shown) and a non-volatile memory that stores the relationship between the temperature and the resistance value of the magnetoresistive element. This non-volatile memory is electrically rewritable. By rewriting the values stored in the non-volatile memory, the gain and offset of the adjustment amplifier 126a are adjusted. With this, the fluctuations in the output of the adjustment amplifier 126a caused by temperature changes can be cancelled out.

The filter 124 includes a resistor 124a and a capacitor 124b. As shown in FIG. 20, on the wiring board 41, a power supply wiring 41d, a first output wiring 41e, a second output wiring 41f, and a ground wiring 41g are formed as wiring patterns.

The ASIC 123 of the first sensing unit 121 is connected to the power supply wiring 41d, the first output wiring 41e, and the ground wiring 41g. An output terminal of the adjustment amplifier 126a of the ASIC 123 of the first sensing unit 121 is connected to the first output wiring 41e.

The resistor 124a of the filter 124 of the first sensing unit 121 is provided on the first output wiring 41e. The capacitor 124b connects the first output wiring 41e and the ground wiring 41g. As a result, the filter 124 of the first sensing unit 121 constitutes a low-pass filter by the resistor 124a and the capacitor 124b. The output of the ASIC 123 of the first sensing unit 121 is output to the ECU via this low-pass filter. As a result, the output of the first sensing unit 121 from which high frequency noise has been removed is input to the ECU.

The ECU 102 is, for example, a battery ECU for a battery that supplies power to a rotating electric machine. For example, the battery ECU, together with an ECU for a rotating electric machine, controls the battery and the rotating electric machine in a coordinated manner. This cooperative control allows the regeneration and power running of the rotating electrical machine to be controlled in accordance with the SOC of the battery. SOC stands for State Of Charge. ECU stands for Electronic Control Unit.

It should be noted that the ECU 102 includes at least one processor circuit that performs the control functions described in this specification. The processor circuit may be provided by a central processing unit (CPU) that executes a program and at least one memory device as a storage medium for storing the program and data. The ECU is implemented by a microcomputer having a computer readable storage medium. The storage medium is a non-transitory tangible storage medium that non-transiently stores a program readable by a computer. The storage medium may be provided by a semiconductor memory or a magnetic disk. The processor circuit may be provided by an analog arithmetic circuit or a logic circuit including a plurality of gate circuits.

The ASIC 123 of the second sensing unit 122 is connected to the power supply wiring 41d, the second output wiring 41f, and the ground wiring 41g. The output terminal of the adjustment amplifier 126a of the ASIC 123 of the second sensing unit 122 is connected to the second output wiring 41f.

The resistor 124a of the filter 124 of the second sensing unit 122 is provided on the second output wiring 41f. The capacitor 124b connects the second output wiring 41f and the ground wiring 41g. As a result, the filter 124 of the second sensing section 122 constitutes a low-pass filter by the resistor 124a and the capacitor 124b. The output of the ASIC 123 of the second sensing unit 122 is output to the ECU via this low-pass filter. As a result, the output of the second sensing unit 122 from which high frequency noise has been removed is input to the ECU.

As described above, the first sensing unit 121 and the second sensing unit 122 of the present embodiment have the same configuration. The magnetoelectric conversion unit 125 of the first sensing unit 121 and the magnetoelectric conversion unit 125 of the second sensing unit 122 are aligned in the axial direction. The magnetic field passing through the magnetoelectric conversion unit 125 of the first sensing unit 121 and the magnetoelectric conversion unit 125 of the second sensing unit 122 are the same.

It is assumed that a constant current flows through the conductive member 10. In this case, the positions and orientations of the two magnetoelectric conversion units 125 with respect to the conductive member 10 (narrowed portion 11c) are set so that the same output is obtained from the two magnetoelectric conversion units 125. In other words, in the above case, the positions and orientations of the two magnetoelectric converting units 125 are adjusted so that equivalent magnetic fields having the same strength and vector components pass through them. For example, the positions and orientations of the two magnetoelectric conversion units 125 relative to the conductive member 10 depend on the position and orientation of the circuit board 41 relative to the conductive member 10, the positions and orientations of the ASICs 123 on the circuit board 41, and the position and orientation of the magnetoelectric conversion unit 125 within each ASIC 123.

A virtual straight line is assumed to pass through the center point of the narrowed portion 11c and extend along the axial direction AD. In the present embodiment, the two magnetoelectric conversion units 125 are arranged side by side on a straight line parallel to the imaginary line. The parallel straight line is spaced a predetermined distance from the imaginary line in the thickness direction TD. In the present embodiment, the two magnetoelectric conversion units 125 are positioned equidistant from the center point of the narrowed portion 11c in the axial direction AD. In the present embodiment, the two magnetoelectric conversion units 125 are positioned within the range of the narrowed portion 11c in the axial direction AD. As a result, when a constant current flows through the conductive member 10, the two magnetoelectric conversion units 125 produce the same output.

Therefore, the electrical signal input from the first sensing unit 121 to the ECU and the electrical signal input from the second sensing unit 122 to the ECU are the same. The ECU 102 compares these two input electrical signals to determine whether or not an abnormality has occurred in either the first sensing unit 121 or the second sensing unit 122. In this manner, the current sensor 1 according to the present embodiment has redundancy.

The shunt resistor 25e may be provided inside the resin part 128 or outside thereof. When provided outside the resin part 128, the shunt resistor 25e is mounted on the wiring board 41. The shunt resistor 25e is externally attached to the ASIC 123.

Furthermore, each of the four resistors constituting the full bridge circuit does not have to be a magnetoresistive element. At least one of these four resistors may be a magnetoresistive element. Instead of a full bridge circuit, only one half bridge circuit may be configured.

In the case where the above-mentioned redundancy is not required, the current sensor 1 may adopt a configuration having either the first sensing unit 121 or the second sensing unit 122. In this case, the sensor element 42 is provided by one sensing unit.

A first shield 51 serving as the magnetic shield member 50 is disposed in the container chamber 23. The shield member 50 has two shields arranged to sandwich the narrowed portion 11c from both sides in the thickness direction TD. Of the two shields, one shield 51 is disposed in the container chamber 23. Of the two shields, the other is disposed on the bottom surface of the sensor housing 21 in the figure.

In the container chamber 23, the wiring board 41 and the shield 51 are arranged in a layered manner. The wiring board 41 and the shield 51 are disposed and fixed to the sensor housing 21 with high positional accuracy in the thickness direction TD. In other words, the wiring board 41 and the shield 51 are disposed and fixed with high positional accuracy relative to the conductive member 10 in the thickness direction TD. The wiring board 41 and the shield 51 are disposed and fixed with high positional accuracy relative to the sensor housing 21 in the axial direction AD. Furthermore, the wiring board 41 and the shield 51 are disposed and fixed with high positional accuracy relative to the sensor housing 21 in the width direction WD. The positional accuracy of the wiring board 41 and the shield 51 also affects the accuracy with which the sensor element 42 detects a current.

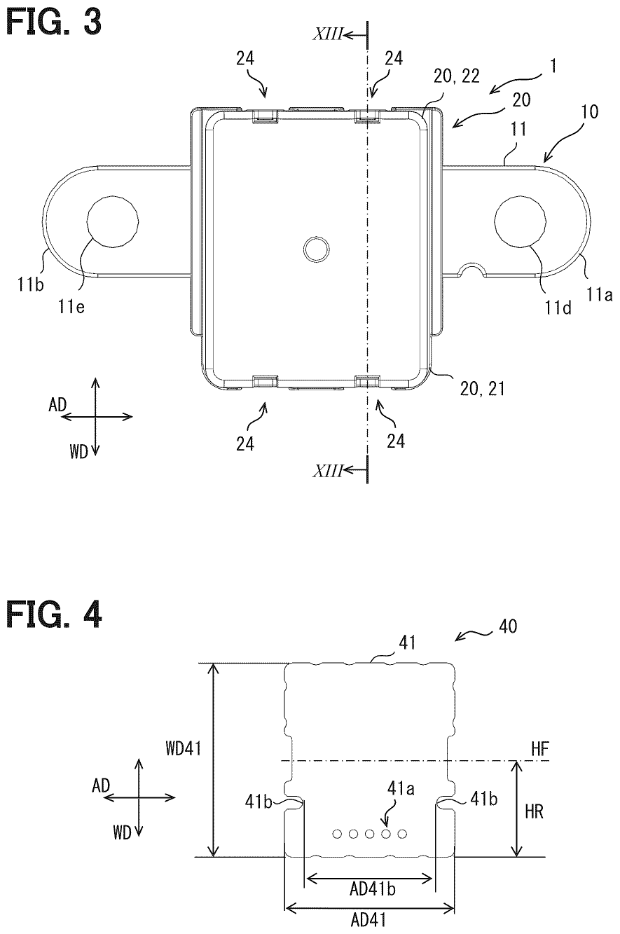

FIG. 3 is a plan view when viewed along an arrow III in FIG. 2. The insulating member 20 is disposed so as to enclose the conductive member 10. The insulating member 20 is a block body disposed at a position in the middle of the conductive member 10. The block body has four coupling mechanisms 24 on its side surfaces in the width direction WD. In other words, the four coupling mechanisms 24 connect the block-shaped insulating member 20 at its four corners.

FIG. 4 is a plan view of the wiring board 41. FIG. 4 is also a plan view of the wiring board 41 when viewed along an arrow VII in FIG. 2. The wiring board 41 is a plate-like member made of an insulating material and including an electric circuit. The wiring board 41 can be provided by a single-layer or multi-layer printed circuit board. The wiring board 41 has a plurality of through holes 41a. The plurality of through holes 41a are through holes that receive terminal pins for the connector 25. The wiring board 41 has a length WD41 in the width direction WD that is greater than a length AD41 in the axial direction AD (i.e., AD41<WD41). Therefore, the wiring board 41 is a rectangular board having a longitudinal direction in the width direction WD. The wiring board 41 has long sides and short sides. The edges of the wiring board 41 are also used as positioning portions.

The wiring board 41 has a positioning notch 41b. The notch 41b is a portion formed in the wiring board 41 and has a characteristic shape. The notch 41b is also called a board notch or a first notch. The position and shape of the notch 41b determine the orientation of the wiring board 41 in an AD-WD plane, which includes the axial direction Ad and the width direction WD, within the container chamber 23 by fitting with a protrusion 28a described below. The orientation of wiring board 41 on the AD-WD plane defined by the notch 41b and the protrusion 28a is a unique orientation.

The wiring board 41 has a plurality of notches 41b. The wiring board 41 has the notches 41b on the long sides. The wiring board 41 has one notch 41b on one long side, and also has another notch 41b on the other long side. A center line HF of the length WD41 in the width direction WD is assumed. In this case, the notches 41b are located in the half region HR on the terminal side than the center line HF. This arrangement is for the purpose of allowing the notches 41b to be accurately positioned so that the through holes 41a can easily receive the terminal pins. This facilitates the arrangement of the wiring board 41 on the sensor housing 21.

The wiring board 41 is substantially symmetrical with respect to the axial direction AD. The two notches 41b are positioned symmetrically with respect to the axial direction AD and have symmetrical shapes. In the present embodiment, the notch 41b is provided by a cutout. The cutout has a shape that recesses inward with respect to the imaginary rectangular outer shape of the wiring board 41. The notch 41b defines a length AD41b in the axial direction AD. The length AD41b is shorter than the length WD41. The length AD41b is shorter than the length AD41. The notch 41b defines the length AD41b, thereby preventing the wiring board 41 from being assembled incorrectly.

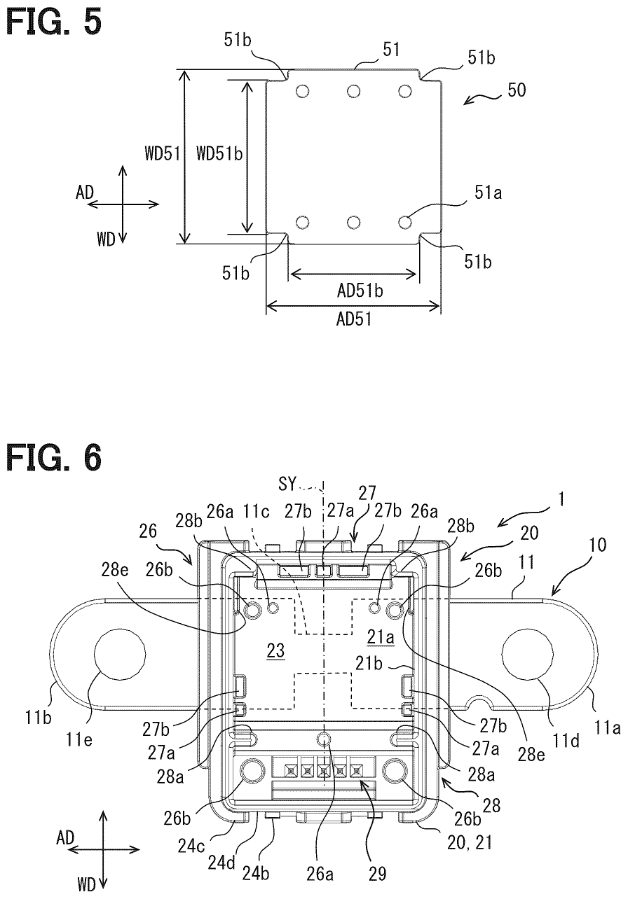

FIG. 5 is a plan view of the first shield. FIG. 5 is also a plan view of the shield 51 when viewed along an arrow VIII in FIG. 2. The shield 51 is a plate-like member in which a plurality of magnetic steel plates are laminated. The steel plate constituting the shield 51 is made of a magnetically anisotropic material having an axis of easy magnetization in the width direction WD. The steel plates are fixed at the press marks 51a. At the press mark 51a, the two steel plates are fixed in a stacked state by meshing with projections and recesses.

The shield 51 has a positioning notch 51b. The shield 51 has a plurality of notches 51b. The shield 51 has notches 51b at the four corners. The notch 51b is a portion formed in the shield 51 and has a characteristic shape. The notch 51b is also called a shield notch or a second notch. The position and shape of the notch 51b determine the orientation of the shield 51 in the AD-WD plane within the container chamber 23 by fitting with a protrusion 28a and a protrusion 28b, which will be described later. The notch 51b and the protrusion 28a, and the notch 51b and the protrusion 28b determine the position of the shield 51 on the AD-WD plane, and define two positions for the shield 51 that are inverted by 180 degrees.

The shield 51 is symmetrical with respect to the axial direction AD. The shield 51 is also symmetrical with respect to the width direction WD. The four notches 51b are positioned symmetrically with respect to the axial direction AD and the width direction WD, and have a symmetrical shape. In the present embodiment, the notch 51b is provided by a cutout. The cutouts have shapes with which the four corners are recessed inward with respect to the imaginary square outline of the shield 51. The notch 51b is provided by a rectangular cutout having a longitudinal direction in the axial direction AD.

The shield 51 has a length AD51 in the axial direction AD. The shield 51 has a length WD51 in the width direction WD. The length AD51 is equal to the length WD51. The notches 51b define a length AD51b in the axial direction AD. The notches 51b define a length WD51b in the width direction WD. The length AD51b is shorter than the length AD51. The length WD51b is shorter than the length WD51. The length AD51b is different from the length WD51b. The length AD51b is shorter than the length WD51b (i.e., AD51b<WD51b). The notches 51b define the length AD51b and the length 51WD51b to be different, thereby preventing the shield 51 from being assembled incorrectly.

FIG. 6 is a plan view when viewed along an arrow VI in FIG. 2. The sensor housing 21 defines the container chamber 23. The sensor housing 21 has a bottom wall 21a. The bottom wall 21a is also a wall made of the insulating material into which the conductive member 10 is inserted. The sensor housing 21 has an outer wall 21b. The outer wall 21b is a wall that extends in the thickness direction TD from the surface of the bottom wall 21a. The outer wall 21b extends annularly in the AD-WD plane. The bottom wall 21a and the outer wall 21b define most of the container chamber 23. The container chamber 23 is defined as a rectangular parallelepiped cavity having a longitudinal direction in the width direction WD.

The sensor housing 21 has a plurality of board support members 26 on the bottom wall 21a. The board support member 26 positions and fixes the wiring board 41 in the thickness direction TD within the container chamber 23. The board support member 26 is a protrusion that protrudes from the bottom wall 21a in the thickness direction TD. The board support member 26 is a columnar member. The board support member 26 is cylindrical. Alternatively, the board support member 26 may be provided with any shape having various cross-sectional shape, such as a hemispherical protrusion, a polygonal column, or an elliptical column. The board support member 26 is also called a board support or a board protrusion.

The plurality of board support members 26 include a plurality of board contact portions 26a. The board contact portion 26a provides positioning by contacting the sensor housing 21 with the wiring board 41. The plurality of board contact portions 26a are provided by the resin material that is continuous from the sensor housing 21. The plurality of board contact portions 26a may be provided by members separate from the sensor housing 21. The board contact portion 26a is also referred to as a board contact pin, a contact board support, or a board support portion. The plurality of board support members 26 include a plurality of board adhesion portions 26b. The board adhesion portion 26b adheres the sensor housing 21 to the wiring board 41 via an adhesive layer 31, which will be described later. The sensor housing 21 and the wiring board 41 are fixed together by the adhesive action of the adhesive layer 31. The plurality of board contact portions 26a contact the wiring board 41 without the adhesive layer 31, thereby accurately determining the position of the wiring board 41 in the thickness direction TD. The plurality of board adhesion portions 26b are provided by a resin material that is continuous from the sensor housing 21. The plurality of board adhesion portions 26b may be provided by members separate from the sensor housing 21. The board adhesion portion 26b is also referred to as a board adhesive pin or an adhesive board support. To allow for the presence of the adhesive layer 31, the tip positions of the plurality of board adhesion portions 26b are farther from the wiring board 41 than the tip positions of the plurality of board contact portions 26a. The tip position may be compared as a height from a reference position of the bottom wall 21a. In this case, the height of the plurality of board adhesion portions 26b is less than the height of the plurality of board contact portions 26a in order to allow for the presence of the adhesive layer 31.

The sensor housing 21 has a plurality of shield support members 27 on the bottom wall 21a. The shield support member 27 positions and fixes the shield 51 in the thickness direction TD within the container chamber 23. The shield support member 27 is a protrusion that protrudes from the bottom wall 21a in the thickness direction TD. The shield support member 27 is a columnar member. The shield support member 27 has a polygonal prism shape. The shield support member 27 may extend along the outer wall 21b. Alternatively, the shield support member 27 may be provided with a variety of cross-sectional shapes, such as a hemispherical projection, a cylindrical shape, an elliptical cylindrical shape, or the like. The shield support member 27 is also referred to as a shield support or a shield protrusion.

The plurality of shield support members 27 include a plurality of shield contact portions 27a. The shield contact portion 27a provides positioning by contacting the sensor housing 21 with the shield 51. The plurality of shield contact portions 27a are provided by a resin material that is continuous from the sensor housing 21. The plurality of shield contact portions 27a may be provided by members separate from the sensor housing 21. The shield contact portion 27a is also referred to as a shield contact pin, a contact shield support, or a shield support portion. The plurality of shield support members 27 include a plurality of shield adhesion portions 27b. The shield adhesion portion 27b adheres the sensor housing 21 to the shield 51 via an adhesive layer 31 described below. The sensor housing 21 and the shield 51 are fixed together by the adhesive action of the adhesive layer 31. The plurality of shield contact portions 27 a contact the shield 51 without the adhesive layer 31, thereby accurately determining the position of the shield 51 in the thickness direction TD. The plurality of shield adhesion portions 27b are provided by a resin material that is continuous from the sensor housing 21. The plurality of shield adhesion portions 27b may be provided by members separate from the sensor housing 21. The shield adhesion portion 27b is also referred to as a shield adhesion pin or an adhesive shield support. To allow for the presence of the adhesive layer 31, the tip positions of the plurality of shield adhesion portions 27b are farther from the wiring board 41 than the tip positions of the plurality of shield contact portions 27a. The tip position may be compared as a height from the reference position of the bottom wall 21a. In this case, the height of the plurality of shield adhesion portions 27b is lower than the height of the plurality of shield contact portions 27a to allow for the presence of the adhesive layer 31.

In order to arrange the wiring board 41 and the shield 51 in a layered manner within the container chamber 23, the tip positions of the plurality of board support members 26 are closer to the reference position of the bottom wall 21a than the tip positions of the plurality of shield support members 27. In other words, in order to arrange the wiring board 41 and the shield 51 in the layered manner within the container chamber 23, the height of the plurality of board support members 26 is lower than the height of the plurality of shield support members 27.

The sensor housing 21 has a plurality of surrounding portions 28. The surrounding portion 28 positions the wiring board 41 and/or the shield 51 in the axial direction AD and the width direction WD within the container chamber 23. The surrounding portion 28 defines the position of the wiring board 41 and the position of the shield 51 in an AD-WD plane. The surrounding portion 28 may fix the wiring board 41 and/or the shield 51. The surrounding portion 28 is disposed at a corner between the bottom wall 21a and the outer wall 21b. The surrounding portion 28 is a small plate-like piece. The surrounding portion 28 has a thickness in the thickness direction TD and is in the form of a plate extending parallel to an AD-TH plane. The surrounding portion 28 gradually tapers off toward the tip in the thickness direction TD. The tapered shape guides the wiring board 41 by loosely fitting into the notch 41b of the wiring board 41 during the process of assembling the wiring board 41 from the opening side of the container chamber 23 toward the bottom wall 21a. The tapered shape transitions the fit between the surrounding portion 28 and the notch 41b from a loose fit to a tight fit. The surrounding portion 28 is provided by a resin material that is continuous from the sensor housing 21. The plurality of surrounding portions 28 may be provided by members separate from the sensor housing 21. The surrounding portion 28 is also referred to as a lateral support because it is positioned laterally of the wiring board 41 and/or the shield 51 and determines their positions.

The plurality of surrounding portions 28 include protrusions 28a. The protrusion 28a is provided by a resin material that is continuous from the sensor housing 21. The plurality of protrusions 28a may be provided by members separate from the sensor housing 21. The protrusion 28a is also referred to as a first lateral support. The protrusion 28a positions the wiring board 41 in the AD-WD plane. The shape of the protrusion 28a is such that it can be fitted with the notch 41b of the wiring board 41. This fitting is relatively tight in both the axial direction AD and the width direction WD to provide accurate positioning. The protrusions 28a are fitted into the notches 41b, thereby accurately positioning the wiring board 41 in both the axial direction AD and the width direction WD.

The protrusion 28a suppresses the wiring board 41 from being disposed in a state in which it is upside down with respect to the width direction WD. In the process of assembling the wiring board 41 to the container chamber 23, it is conceivable that the assembling operation may be attempted with the wiring board 41 inverted with respect to the width direction WD. In the case of incorrect assembly, the protrusions 28a will not be able to fit properly with the wiring board 41. Therefore, the wiring board 41 is not disposed at a specified position within the container chamber 23. As a result, the worker can easily notice any incorrect assembly. Therefore, incorrect assembly can be reliably suppressed.

Furthermore, the protrusion 28a also functions as a member for positioning the shield 51 in relation to the shield 51. In other words, the protrusion 28a positions both the wiring board 41 and the shield 51 in the AD-WD plane.

In the case of the above-mentioned incorrect assembly, since the wiring board 41 is disposed on the protrusions 28a, even if an attempt is subsequently made to assemble the shield 51, the positioning of the shield 51 is also impossible. As a result, the shield 51 cannot be placed at a specified position within the container chamber 23 either. This allows the worker to easily notice any incorrect assembly. Therefore, incorrect assembly can be reliably suppressed.

The plurality of surrounding portions 28 include protrusions 28b. The protrusion 28b is provided by a resin material that is continuous from the sensor housing 21. The plurality of protrusions 28b may be provided by members separate from the sensor housing 21. The protrusion 28b is also referred to as a second lateral support. The protrusions 28a and 28b cooperate to position the shield 51 in the AD-WD plane. The shapes of the protrusions 28a and 28b are such that they can fit with the notches 51b at the four corners of the shield 51.

The protrusions 28b are disposed at the corners of the outer wall 21b. The protrusion 28b is a raised portion whose length in the axial direction AD and whose length in the width direction WD are different. The protrusion 28b is a rectangular protruding portion whose length in the axial direction AD is longer than its length in the width direction WD.

The sensor housing 21 has two protrusions 28b. The two protrusions 28b are disposed apart from each other in the axial direction AD. Between the two protrusions 28b, a gap capable of accommodating the length AD51b in the axial direction AD is provided. The gap is long enough to receive the side of the shield 51 having the length AD51b with high precision. The gap is set so as not to be able to accommodate the side of the shield 51 with the length AD51. The two protrusions 28a have a shape that functions as the protrusions 28b. In this respect, the protrusion 28a is also the protrusion 28b. The two protrusions 28a are disposed apart from each other in the axial direction AD. Between the two protrusions 28a, a gap capable of accommodating the length AD51b of the shield 51 in the axial direction AD is provided. The gap is long enough to receive the side of the shield 51 having the length AD51b with high precision. The gap is set so as not to be able to accommodate the side of the shield 51 with the length AD51.

In this manner, the two protrusions 28a provide an axial pair of surrounding portions 28 that position the shield 51 with respect to the axial direction AD. In addition, the two protrusions 28b provide an axial pair of surrounding portions 28 that position the shield 51 with respect to the axial direction AD. As a result, the sensor housing 21 provides two axial pairs by the four surrounding portions 28.

One protrusion 28a and one protrusion 28b are disposed apart from each other in the width direction WD. Between the protrusions 28a and 28b, a gap capable of accommodating the length WD51b of the shield 51 in the width direction WD is provided. The gap is long enough to receive the side of the shield 51 with length WD51b with high precision. The gap is set so as not to be able to accommodate the side of the shield 51 with the length WD51.

In this manner, the sensor housing 21 has one protrusion 28a and one protrusion 28b positioned apart from each other in the width direction WD. These provide a widthwise pair of surrounding portions 28 that position the shield 51 in the width direction WD. The sensor housing 21 provides two widthwise pairs by the four surrounding sections 28. These four surrounding portions 28 provide positioning portions with respect to two perpendicular axes directions (the axial direction AD and the width direction WD).

The plurality of surrounding portions 28 include protrusions 28e. The protrusion 28e is provided by a resin material that is continuous from the sensor housing 21. The plurality of protrusions 28e may be provided by members separate from the sensor housing 21. The protrusion 28e is also referred to as a third lateral support. The protrusions 28a and 28e cooperate to position the wiring board 41 in the AD-WD plane. The shape of the protrusion 28e is such that it can come into contact with the edge of the wiring board 41. The shape of the protrusion 28e provides a fitting relationship between the wiring board 41 and the sensor housing 21. The protrusion 28e is lower than the protrusions 28a and 28b in the thickness direction TD. The protrusion 28e contacts the wiring board 41 in the axial direction AD and the width direction WD, but does not contact the shield 51 in the axial direction AD and the width direction WD.

The sensor housing 21 has four surrounding portions 28, providing the two axial pairs and the two widthwise pairs. The two axial pairs and the two widthwise pairs position the shield 51 with high precision in both the axial direction AD and the width direction WD.

The protrusions 28a and 28b suppress the shield 51 from being disposed with its axial direction AD and width direction WD reversed. This is effective for aligning the axis of easy magnetization of the shield 51 with the width direction WD. In the process of assembling the shield 51 to the container chamber 23, it is assumed that the assembly work is attempted in a state in which the shield 51 is rotated 90 degrees. In the case of incorrect assembly, the protrusions 28a and 28b will not be able to fit with the shield 51. Therefore, the shield 51 is not disposed at a specified position within the container chamber 23. As a result, the worker can easily notice any incorrect assembly. Therefore, incorrect assembly can be reliably suppressed.

The plurality of board support members 26 and the plurality of shield support members 27 are disposed within the container chamber 23 on the inner side of the outer wall 21b. The plurality of board support members 26 and the plurality of shield support members 27 are disposed in a dispersed manner. The plurality of surrounding portions 28 are disposed on the inner surface of the outer wall 21b. The plurality of surrounding portions 28 are disposed in a dispersed manner inside the outer wall 21b. The plurality of surrounding portions 28 are disposed within the container chamber 23 so that the wiring board 41 can be disposed within the container chamber 23 only in a specified orientation. The plurality of surrounding portions 28 are disposed within the container chamber 23 so that the shield 51 can be placed within the container chamber 23 only in a specified position.

The sensor housing 21 has a plurality of connector pins 29. The plurality of connector pins 29 are electrically connected to the electric circuit provided by the wiring board 41 by positioning the wiring board 41 in the specified position.

A line of symmetry SY can be imagined at the center of the narrowed portion 11c in the axial direction AD. In this case, the shape of the sensor housing 21 is axisymmetric with respect to the line of symmetry SY. The outer wall 21b extends symmetrically with respect to the line of symmetry SY. The plurality of board support members 26 are arranged symmetrically with respect to the line of symmetry SY. The plurality of shield support members 27 are arranged symmetrically with respect to the line of symmetry SY. The plurality of surrounding portions 28 are arranged symmetrically with respect to the line of symmetry SY. The plurality of connector pins 29 are arranged symmetrically with respect to the line of symmetry SY. Furthermore, the plurality of elements constituting the current sensor 1 are symmetrical with respect to the line of symmetry SY. The multiple elements constituting the current sensor 1 are symmetrical with respect to the line of symmetry SY at least in the vicinity of the narrowed portion 11c. The conductor member 11 has a line symmetric shape with respect to the line of symmetry SY in the vicinity of the narrowed portion 11c. The insulating member 20 has a line symmetric shape with respect to the line of symmetry SY. The electric circuit component 40 has a configuration that is line symmetrical with respect to the line of symmetry SY. The shield member 50 has a line symmetric shape with respect to the line of symmetry SY.

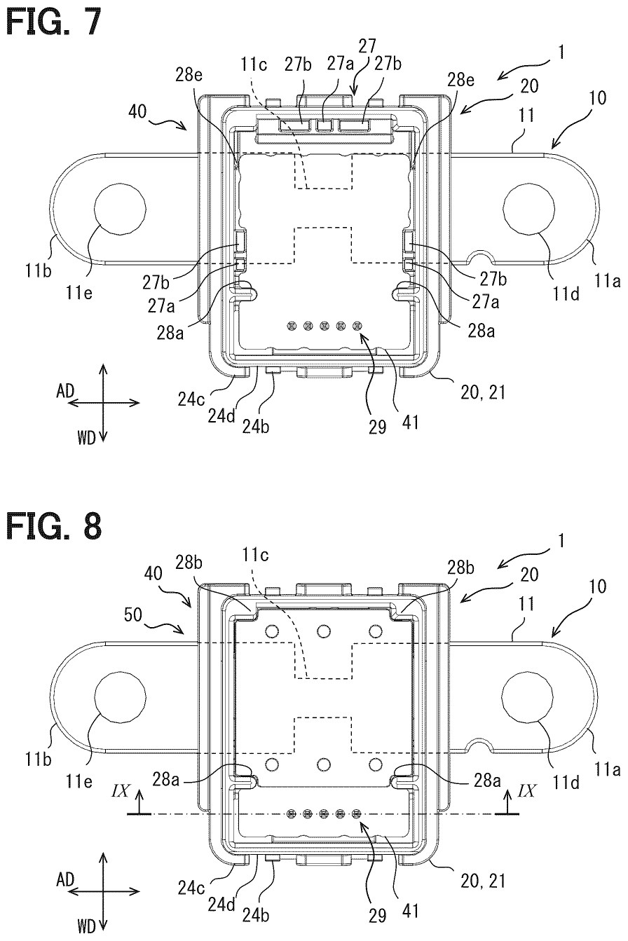

FIG. 7 is a plan view when viewed along an arrow VII in FIG. 2. Only the wiring board 41 is attached to the sensor housing 21. The plurality of board support members 26 are covered and hidden by the wiring board 41. In this state, only the shield support members 27 are visible.

FIG. 8 is a plan view when viewed along an arrow VIII in FIG. 2. Both the wiring board 41 and the shield 51 are assembled to the sensor housing 21 in a layered manner. The wiring board 41 is disposed between the shield 51 and the sensor housing 21. The plurality of board support members 26 are covered and hidden by the wiring board 41. Furthermore, in this state, the plurality of shield support members 27 are also covered and hidden by the shield 51.

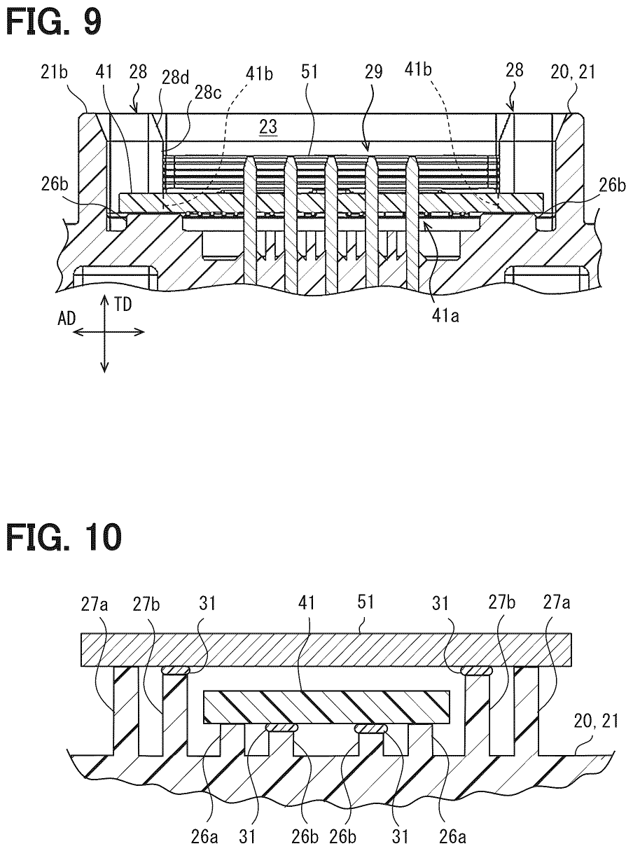

FIG. 9 is a cross-sectional view taken along a line IX-IX in FIG. 2. The plurality of connector pins 29 are held in the sensor housing 21. The plurality of connector pins 29 may be embedded in the sensor housing 21 by insert molding. The plurality of connector pins 29 may be inserted into the sensor housing 21 which is a resin molded product. One ends of the connector pins 29 protrude into the container chamber 23. Furthermore, the plurality of connector pins 29 are inserted into the through holes 41a of the wiring board 41. The plurality of connector pins 29 are electrically connected to the electric circuit provided by the wiring board 41.

The wiring board 41 is supported by being in contact with the board contact portion 26a of the sensor housing 21. The wiring board 41 is engaged with the surrounding portions 28 at the notches 41b. The notches 41b and the surrounding portions 28 form a fitting relationship, thereby positioning the wiring board 41 in both the axial direction AD and the thickness direction TD.

The surrounding portions 28 includes the protrusions 28a and the protrusions 28b. The protrusion 28a has a plate shape. The protrusion 28a protrudes in a plate shape from the inner surface of the surrounding portion 28. The protrusion 28b has a protruding shape. The protrusion 28a protrudes in the shape of a rectangular parallelepiped from the corner of the inner surface of the surrounding portion 28. The shape of the side surface of the protrusion 28a and the shape of the side surface of the protrusion 28b correspond to each other and have the same shape. In the following description, a vertical surface 28c and an inclined surface 28d of the surrounding portion 28 are formed in both the shape of the side surface of the protrusion 28a and the shape of the side surface of the protrusion 28b.

The surrounding portion 28 has a portion having the vertical surface 28c extending along the thickness direction TD. This vertical surface 28c forms a tight fit with the notch 41b or the notch 51b. Furthermore, the surrounding portion 28 has a tapered shape at its tip in the thickness direction TD. The tapered shape is provided by the inclined surface 28d that is inclined with respect to the thickness direction TD.

In the process of placing the wiring board 41 in the container chamber 23, the inclined surface 28d forms a loose fit with the notch 41b. When the wiring board 41 is inserted into the container chamber 23 through the opening of the container chamber 23, the inclined surface 28d guides the wiring board 41 by loosely fitting with the notch 41b. In the process of placing the wiring board 41 at the specified position in the container chamber 23, the fit between the notch 41b and the protrusion 28a gradually and smoothly transitions from the loose fit to a tight fit.

The inclined surface 28d forms a loose fit with the notch 51b during the process of placing the shield 51 within the container chamber 23. When the shield 51 is inserted into the container chamber 23 through the opening of the container chamber 23, the inclined surface 28d guides the shield 51 by loosely fitting with the notch 51b. In the process of placing the shield 51 at the specified position in the container chamber 23, the fit between the four notches 51b and the two protrusions 28a and the two protrusions 28b gradually and smoothly transitions from the loose fit to a tight fit.

FIG. 10 is a modeled cross-sectional view. Here, the support state (including both an adhered state and a contact state) of the wiring board 41 and the shield 51 with respect to the sensor housing 21 is illustrated.

The wiring board 41 is supported relative to the sensor housing 21 by the plurality of board support members 26. The wiring board 41 is in mechanical contact with the top surfaces of the plurality of board contact portions 26a. The plurality of board contact portions 26a define the position of the wiring board 41 relative to the sensor housing 21. Therefore, the wiring board 41 is positioned and supported with respect to the sensor housing 21 by the plurality of board contact portions 26a. The wiring board 41 is accurately positioned without any variable factor such as the adhesive layer 31. The number of the plurality of board contact portions 26a is selected from three, four, five, or the like so that the wiring board 41 can be stably supported. Further, the plurality of board contact portions 26a are arranged in a dispersed manner within the container chamber 23 so that the wiring board 41 is stabilized.

The wiring board 41 is adhered to the sensor housing 21 by the adhesive layer 31 disposed between the top surfaces of the plurality of board adhesion portions 26b and the wiring board 41. The adhesive layer 31 is adhered to the wiring board 41 on one side, and to the top surfaces of the plurality of board adhesion portions 26b on the other side. The plurality of board adhesion portions 26b and the adhesive layer 31 fix the wiring board 41 to the sensor housing 21 by adhesion. The adhesive layer 31 is an adhesive after cured. The adhesive layer 31 is also called a cured adhesive layer. The wiring board 41 is fixed via a variable element such as an adhesive layer 31. The number of the board adhesion portions 26b is selected from three, four, five, or the like so that the wiring board 41 can be stably supported and an appropriate adhesive force can be obtained. Further, the plurality of board adhesion portions 26b are arranged in a dispersed manner within the container chamber 23 so that the wiring board 41 is stabilized.

The height of the top surface of the board adhesion portion 26b is lower than the height of the top surface of the board contact portion 26a so as to allow for the presence of the adhesive layer 31. The difference in height between the top surface of the board contact portion 26a and the top surface of the board adhesion portion 26b corresponds to the thickness of the adhesive layer 31. Here, the height of the top surfaces of the plurality of board support members 26 can be the height in the thickness direction TD from any portion of the bottom wall 21a facing the container chamber 23.

According to the configuration shown in the figure, accurate positioning of the wiring board 41 relative to the sensor housing 21 is achieved by the plurality of board contact portions 26a, and adhesion, i.e., fixation, of the wiring board 41 to the sensor housing 21 is achieved by the plurality of board adhesion portions 26b and the adhesive layer 31.

The shield 51 is supported relative to the sensor housing 21 by the plurality of shield support members 27. The shield 51 is in mechanical contact with the top surfaces of the plurality of shield contact portions 27a. The plurality of shield contact portions 27a define the position of the shield 51 relative to the sensor housing 21. Therefore, the shield 51 is positioned and supported with respect to the sensor housing 21 by the plurality of shield contact portions 27a. The shield 51 is precisely positioned without a variable element such as an adhesive layer 31. The number of the plurality of shield contact portions 27a is selected from three, four, five, or the like so as to stably support the shield 51. Further, the plurality of shield contact portions 27a are disposed in a dispersed manner within the container chamber 23 so that the shield 51 is stabilized.

The shield 51 is adhered to the sensor housing 21 by the adhesive layer 31 disposed between the top surfaces of the plurality of shield adhesion portions 27b and the shield 51. The adhesive layer 31 is adhered to the shield 51 on one side, and to the top surfaces of the plurality of shield adhesion portions 27b on the other side. The plurality of shield adhesion portions 27b and the adhesive layer 31 fix the shield 51 to the sensor housing 21 by adhesive. The adhesive layer 31 is an adhesive after cured. The adhesive layer 31 is also referred to as a cured adhesive layer. The shield 51 is fixed via a variable element such as an adhesive layer 31. The number of the plurality of shield adhesion portions 27b is selected from three, four, five, or the like so that the shield 51 can be stably supported and an appropriate adhesive force can be obtained. Further, the plurality of shield adhesion portions 27b are arranged in a dispersed manner within the container chamber 23 so that the shield 51 is stabilized.

The height of the top surface of the shield adhesion portion 27b is lower than the height of the top surface of the shield contact portion 27a so as to allow for the presence of the adhesive layer 31. The difference in height between the top surface of the shield contact portion 27a and the top surface of the shield adhesion portion 27b corresponds to the thickness of the adhesive layer 31. Here, the height of the top surfaces of the plurality of shield support members 27 can be regarded as the height in the thickness direction TD from any portion of the bottom wall 21a facing the container chamber 23.

According to the illustrated configuration, accurate positioning of the shield 51 relative to the sensor housing 21 is achieved by the plurality of shield contact portions 27a, and adhesion, i.e., fixation, of the shield 51 to the sensor housing 21 is achieved by the plurality of shield adhesion portions 27b and the adhesive layer 31.

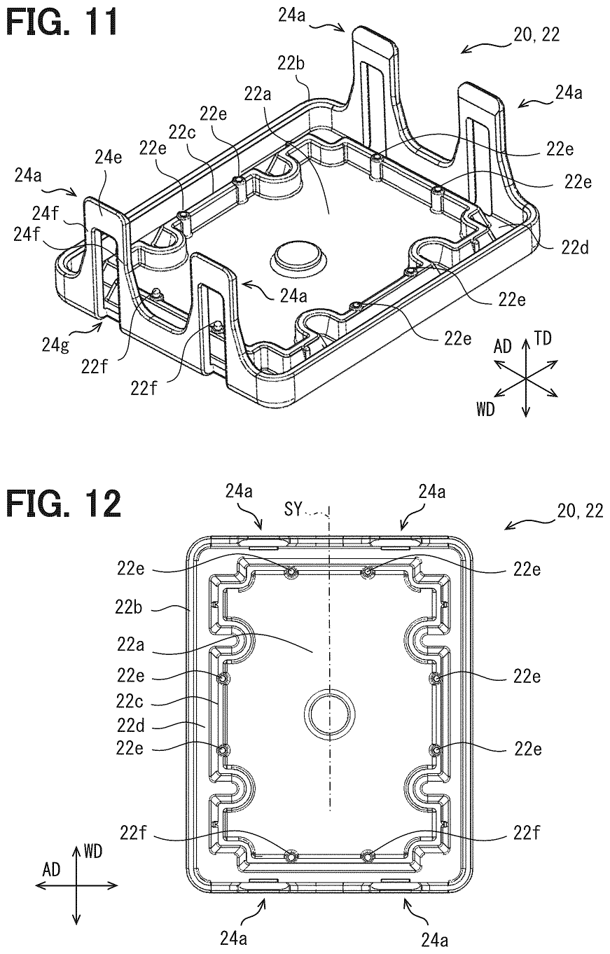

FIG. 11 is a perspective view of the cover 22. FIG. 12 is a rear view showing the inside of the cover 22. These figures show the inner surface of the cover 22.

The cover 22 has a main body portion 22a. The main body portion 22a can be referred to as being shaped like a rectangular plate or a shallow rectangular dish. The cover 22 has an outer edge 22b having a predetermined height in the thickness direction TD at the edge of the main body portion 22a. Furthermore, the cover 22 has an inner edge 22c located more to inside than the outer edge 22b. The inner edge 22c also has a predetermined height in the thickness direction TD. The outer edge 22b and the inner edge 22c define an annular seal chamber 22d therebetween. The seal chamber 22d can receive the outer wall 21b of the sensor housing 21 therein.

The cover 22 has the plurality of engagement arms 24a. When the engagement arm 24a of the cover 22 and the engagement claw 24b of the sensor housing 21 are connected to each other, the seal chamber 22d and the outer wall 21b are fitted together. As a result, the container chamber 23 is defined between the sensor housing 21 and the cover 22. Additionally, the inner edge 22c may have a slope that contacts the outer wall 21b.

The cover 22 has at least one shield pressing portion 22e. The cover 22 has a plurality of shield pressing portions 22e. The plurality of shield pressing portions 22e enable stable support of the shield 51. The shield pressing portion 22e protrudes from the inner edge 22c in the thickness direction TD. The shield pressing portion 22e has a thin columnar shape. The shield pressing portion 22e has a cylindrical shape. The shield pressing portion 22e can also be referred to as a protrusion. Alternatively, the shield pressing portion 22e may be provided to have various cross-sectional shapes, such as a hemisphere, a polygonal column, or an elliptical column. The shield pressing portion 22e is provided by a resin material that is continuous from the cover 22. The shield pressing portion 22 e may be provided by a member separate from the cover 22. The shield pressing portion 22e is also referred to as a shield pressing pin or a shield back support. The shield pressing portions 22e support the shield 51 by the elastic force of a plurality of members included in the cover 22.

The plurality of shield pressing portions 22e are disposed in a dispersed manner along three of the four sides of the inner edge 22c. In other words, the plurality of shield pressing portions 22e are disposed in a dispersed manner along the edge of the shield 51. The dispersed arrangement of the plurality of shield pressing portions 22e contributes to stable support of the shield 51. In the present embodiment, two shield pressing portions 22e are disposed on one side of the inner edge 22c. The remaining one of the four sides of the inner edge 22c is located outside the range of the shield 51. On the remaining one of the four sides of the inner edge 22c, a protrusion 22f is disposed in place of the shield pressing portion 22e. The shield pressing portion 22e is in contact with the shield 51 in a specific range on the other surface of the shield 51. The specific range is the range along the edge of the shield 51. The specific range is a range that can be referred to as the opposite side to the contact range of the shield contact portion 27a. In the present embodiment, the specific range is a strip-shaped range extending along the edge of the shield 51. As a result, the shield 51 is sandwiched between the shield contact portion 27a and the shield pressing portion 22e. The shield contact portion 27a and the shield pressing portion 22e are positioned to have a substantially opposing relationship on both sides of the shield 51, so that the position of the shield 51 is stably maintained. The position of the shield contact portion 27a and the position of the shield pressing portion 22e are in a substantially opposing relationship in the thickness direction TD on both sides of the shield 51. Note that the nearly opposing positional relationship is not a mathematical positional relationship. The substantially opposing positional relationship includes a tolerance range within which the shield 51 is not tilted. For example, the substantially opposing positional relationship includes a state in which the position of the shield contact portion 27a and the position of the shield pressing portion 22e are located along the same side of the shield 51. Additionally or alternatively, the substantially opposing positional relationship includes a state in which the position of the shield contact portion 27a and the position of the shield pressing portion 22e are offset from each other by a range of several millimeters to several centimeters.

The line of symmetry SY can be imagined at the center of the cover 22 in the axial direction AD. In this case, the shape of the cover 22 is symmetrical with respect to the line of symmetry SY. The plurality of shield pressing portions 22e are arranged at approximately equal intervals along the inner edge 22c in order to contact the shield 51 evenly.

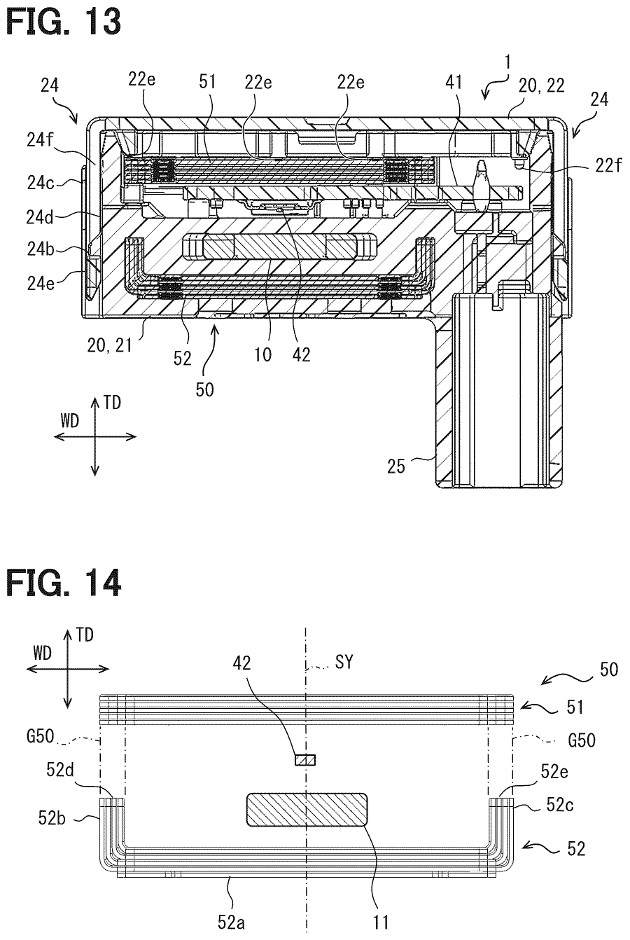

FIG. 13 is a cross-sectional view of the current sensor 1. The figure shows a cross section taken along a line XIII-XIII in FIG. 2. It should be noted that the line XIII-XIII is merely an example, and may be taken through a somewhat complicated cross section to aid in understanding the shape of the part.

The shield pressing portion 22e is in contact with the shield 51 when the cover 22 is connected to the sensor housing 21. The shield 51 is adhered to the sensor housing 21 by the shield adhesion portion 27b and the adhesive layer 31, and is thus fixed. The cover 22 prevents the shield 51 from moving in the thickness direction TD by contacting with the shield 51 at the shield pressing portion 22e. In other words, the shield 51 is supported by the contact with the shield contact portion 27a on one surface, and is supported by the contact with the shield pressing portion 22e on the other surface. The shield 51 is disposed between the shield contact portion 27a and the shield pressing portion 22e. As a result, the position of the shield 51 is stably maintained in the thickness direction TD. For example, it is conceivable that the adhesive strength of the adhesive layer 31 may be weakened due to peeling of the adhesive layer 31 or cracks in the adhesive layer 31. Even in such a case, the shield 51 is kept being accurately positioned by the shield contact portion 27a and the shield pressing portion 22e. In an extreme case, even if the adhesive strength of the adhesive layer 31 is completely lost, the shield pressing portion 22e suppresses the shield 51 from floating up.

In FIG. 13, the shield member 50 is disposed so as to sandwich the conductive member 10 and the sensor element 42 from both sides in the thickness direction TD. The shield member 50 forms a magnetic path surrounding the conductive member 10. The shield member 50 forms a loop-shaped magnetic path surrounding the conductive member 10 and the sensor element 42. The shield member 50 is disposed so as to magnetically protect the conductive member 10 and the sensor element 42. The shield member 50 includes a first shield 51 and a second shield 52. The shield member 50 may be provided by only the shield 51, by only the shield 52, or by shield(s) having different shape(s).

The current sensor 1 detects a magnetic flux induced by the current flowing through the conductive member 10, and outputs an electrical signal indicating the amount of current. The current flowing through the conductive member 10 generates a normal magnetic flux as a target to be detected. A portion of this magnetic flux is detected by the sensor element 42. In the following description, the magnetic flux generated due to the current flowing through the conductive member 10 may be referred to as a normal magnetic flux. On the other hand, when the current sensor 1 is located in a magnetic field of another magnetic source, a magnetic flux caused by the other magnetic source may be referred to as an external magnetic flux. The external magnetic flux imparts a noise component to the output of the current sensor 1.

A magnetic source external to the current sensor 1 may provide an external magnetic flux that attempts to reach the sensor element 42 from outside of the current sensor 1. The external magnetic flux appears as a noise component in the output of the sensor element 42. The external magnetic flux reduces the detection accuracy of the current sensor 1. The shield member 50 captures the external magnetic flux. The shield member 50 restricts the external magnetic flux from reaching the sensor element 42. Preferably, the shield member 50 blocks the external magnetic flux from reaching the sensor element 42. Thus, the shield member 50 provides a magnetic shield.

From another point of view, a part of the normal magnetic flux tends to leak out to the outside of the current sensor 1 as leakage magnetic flux. Fluctuations in the amount of leakage magnetic flux and in the path of the leakage magnetic flux may cause fluctuations in the magnetic flux to be detected that intersects with the sensor element 42. The shield member 50 captures the normal magnetic flux. The shield member 50 suppresses the leakage magnetic flux. As a result, the shield member 50 suppresses fluctuations in the magnetic flux inside the shield member 50, i.e., fluctuations in the normal magnetic flux linking the sensor element 42, which are caused by fluctuations in the leakage magnetic flux. From this this point of view, the shield member 50 also provides the magnetic shield.

FIG. 14 is a side view showing the magnetic shield. The shield member 50 is a member that magnetically protects the sensor system including the conductive member 10 and the sensor element 42. The shield member 50 is disposed at least at a part around the conductive member 10 and the sensor element 42, and defines a magnetic gap G50. The shield 51 has a quadrilateral plate shape in the TD-WD plane perpendicular to the axial direction AD. The shield 52 has a central portion 52a having a quadrilateral plate shape. Furthermore, the shield 52 has an extension portion 52b extending in the thickness direction TD from one end of the central portion 52a in the width direction WD. The shield 52 has an extension portion 52c extending in the thickness direction TD from the other end of the central portion 52a in the width direction WD. The shield 52 has a central portion 52a and two extension portions 52b and 52c. The extensions 52b and 52c are also referred to as arm portions. As a result, the shield 52 has a shape that can be referred to as a U-shape or a bracket shape in the TD-WD plane perpendicular to the axial direction AD. A portion of the surface of the shield 51 faces an end face of the extension portion 52b facing in the thickness direction TD. Another portion of the surface of the shield 51 faces an end face of the extension portion 52c facing in the thickness direction TD. A magnetic gap G50 is formed between the shield 51 and the shield 52. The shield member 50 has two gaps G50 corresponding to positions that can be referred to as both ends of the shield 51 or both ends of the shield 52.

According to the present embodiment, even if there is an external magnetic flux in the thickness direction TD, the shield 51 and the central portion 52a restricts the external magnetic flux from reaching the sensor element 42. Furthermore, even if there is an external magnetic flux in the width direction WD, the extension portions 52b and 52c suppress the external magnetic flux from reaching the sensor element 42.

In the present embodiment, the conductive member 10, the sensor element 42, and the shield member 50 are disposed symmetrically with respect to the line of symmetry SY. The conductive member 10, the sensor element 42 and the shield member 50 are magnetic elements in the current sensor 1. The line of symmetry SY is an axis that passes through the sensor element 42 and extends along the thickness direction TD. The magnetic elements are arranged and shaped symmetrically with respect to the line of symmetry SY. Such symmetrical arrangement and shape contribute to suppressing fluctuations in the magnetic flux in the sensor element 42.

Returning to FIG. 13, in the magnetic gap G50 between the shield 51 and the shield 52, the insulating material forming the sensor housing 21 and the wiring board 41 are disposed. The magnetic gap G50 is also referred to as an air gap even though some non-magnetic material is present. The presence of magnetic gap G50 suppress magnetic saturation from occurring in the shield 51 and/or the shield 52 due to the normal magnetic flux. Furthermore, the relative positional relationship between the magnetic gap G 50 and the sensor element 42 is set so as to suppress a magnetic flux linking with the sensor element 42 due to residual magnetization in the shield member 50.

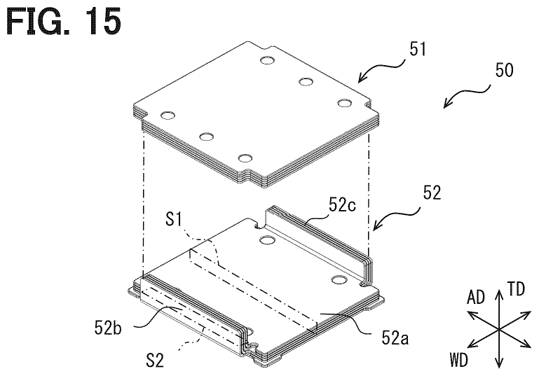

FIG. 15 is a perspective view showing a magnetic shield. The shields 51 and 52 are formed as plate-like members each having a predetermined thickness by laminating a plurality of steel plates. In the following description, the magnetic path cross-sectional area is the cross-sectional area in a cross section perpendicular to the looped magnetic path provided by the shield member 50. The central portion 52a of the shield 52 has a magnetic path cross-sectional area S1 in a cross section parallel to the AD-TD plane. In other words, the magnetic path cross-sectional area S1 is the magnetic path cross-sectional area of the shield at the portion of the magnetic path that is farthest from the magnetic gap G50. The extension portion 52b of the shield 52 has a magnetic path cross-sectional area S2 in a cross section parallel to the AD-WD plane. The extension portion 52c of the shield 52 also has a magnetic path cross-sectional area S2 in a cross section parallel to the AD-WD plane. In other words, the magnetic path cross-sectional area S2 of the extensions 52b, 52c is the magnetic path cross-sectional area of the shield in the portion close to the magnetic gap G50. The magnetic path cross-sectional area S1 is larger than the magnetic path cross-sectional area S2 (S1>S2). Therefore, the magnetic path cross-sectional area S1 of the shield at the portion 52a that is the furthest from the magnetic gap G50 in the magnetic path is larger than the magnetic path cross-sectional area S2 of the shield at the portions 52b and 52c that are closer to the magnetic gap G50.

The shield member 50 has a first portion in the magnetic path formed by the shield member 50 that is spaced apart from the gap G50. Furthermore, the shield member 50 has a second portion that is closer to the gap G50 than the first portion. The central portion 52a forms a first section. The first extension portion 52b or the second extension portion 52c forms a second portion. The shield member 50 is formed such that, with respect to the cross-sectional area of the magnetic path, the cross-sectional area S1 of the magnetic path at the first portion (the central portion 52a) is larger than the cross-sectional area S2 of the magnetic path at the second portion (the first extension portion 52b and the second extension portion 52c).

Here, it is assumed that partial magnetic saturation occurs in a portion of the shield member 50 in the annular direction. In this case, the external magnetic flux may pass through the magnetically saturated portion and reach the sensor element 42. For example, the normal magnetic flux induced by the current flowing through conductive member 10 may cause the partial magnetic saturation. Here, it is assumed that magnetic saturation may occur in a range of the shield member 50 that includes the portion closest to the sensor element 42. In this case, the effect of the external magnetic flux on the sensor element 42 is large.

Furthermore, if the magnetic saturation occurs in a portion of the shield member 50, the normal magnetic flux passing through the sensor element 42 also changes. For example, if the magnetic saturation occurs only in the shield 52, the distribution of magnetic flux density around the conductive member 10 will vary. In other words, the balance of the magnetic flux density around the conductive member 10 fluctuates. As a result, the magnetic flux passing through the sensor element 42 also fluctuates.

In the shield 52 in which the magnetic path cross-sectional area S1 is set to be larger than the magnetic path cross-sectional area S2, the magnetic saturation is unlikely to occur in the magnetic path cross-sectional area S1. As a result, the situation in which external magnetic flux passes through the central portion 52a of the shield 52 and reaches the sensor element 42 is suppressed.

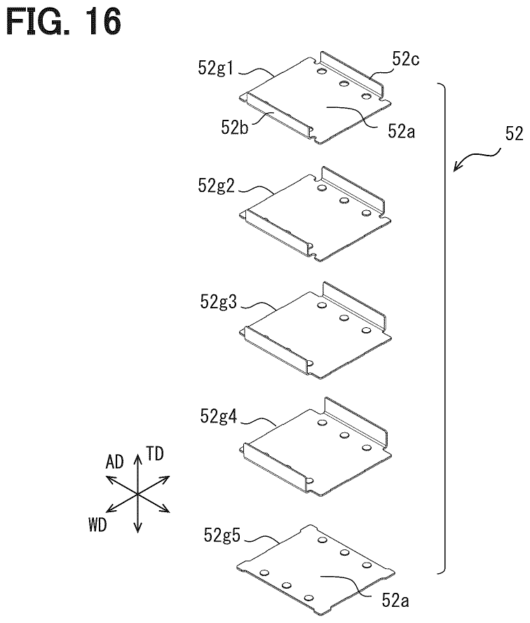

FIG. 16 is an exploded perspective view of the shield. The shield 51 and the shield 52 are each provided by a stacked body in which a plurality of steel plates are stacked and connected. In particular, the shield 52 is formed by stacking bracket-shaped steel plates 52g1, 52g2, 52g3, and 52g4 and a flat steel plate 52g5 in order to provide the relationship between the magnetic path cross-sectional area S1 and the magnetic path cross-sectional area S2. The steel plates 52g1, 52g2, 52g3, and 52g4 are also referred to as first steel plates. The steel plate 52g5 is also referred to as a second steel plate. The steel plates 52g1, 52g2, 52g3, and 52g4 each have the central portion 52a, the extension portion 52b, and the extension portion 52c. The extension portion 52b extends from one end of the central portion 52a toward the first shield 51. The extension portion 52b faces the first shield 51 to define the gap G50. The extension portion 52b is also referred to as a first extension portion. The extension portion 52c extends from the other end of the central portion 52a toward the first shield 51. The extension portion 52c faces the first shield 51 to define the gap G50. The extension portion 52c is also referred to as a second extension portion. The steel plate 52g5 has only the central portion 52a.

These steel plates 52g1, 52g2, 52g3, 52g4, and 52g5 are stacked and connected at the press marks, thereby realizing the relationship between the magnetic path cross-sectional area S1 and the magnetic path cross-sectional area S2. Even in this configuration, the shield member 50 has, in the magnetic path formed by the shield member 50, the first portion 52a that is distant from the gap G50, and the second portions 52b and 52c that are closer to the gap G50 than the first portion 52a. The shield member 50 is formed so that the number M of the stacked steel plates in the first portion 52a is greater than the number N of the stacked steel plates in the second portions 52b and 52c (M>N).

Therefore, the plurality of first steel plates 52g1, 52g2, 52g3, and 52g4 are arranged in a stacked manner in each of the central portion 52a, the first extension portion 52b, and the second extension portion 52c. The first steel plates 52g1, 52g2, 52g3 and 52g4 and the second steel plate 52g5 are arranged in a stacked manner in the central portion 52a. The second steel plate 52g5 is disposed on the opposite side to the direction in which the first extension portion 52b and the second extension portion 52c extend.

The magnetic path cross-sectional area S1 of the shield at the portion 52a that is the furthest from the magnetic gap in the magnetic path is realized by the stacking the steel plates with the number of M. The magnetic path cross-sectional area S2 of the shield at the portions 52b and 52c close to the magnetic gap in the magnetic path is realized by stacking the steel plates with the number of N. The number M of the steel plates in the portion 52a is greater than the number N of the steel plates in the portions 52b and 52c (M>N). The number P of the first steel plates 52g1, 52g2, 52g3, and 52g4 is greater than the number Q of the second steel plates 52g5 (P>Q).

In the present embodiment, the steel plates with the number of M are stacked in the portion 52a. In the portions 52b and 52c, the steel plates with the number of N are stacked. In the present embodiment, the second shield 52 has the first steel plates 52g1, 52g2, 52g3, 52g4 with the number of O and the second steel plate 52g5 with the number of Q. In other words, the number M of the steel plates in the central portion 52a of the shield 52 is greater than the number N of the steel plates in the extension portions 52b and 52c. The difference between the number M and the number N can be adjusted to 1, 2, 3, 4, or the like, depending on the expected magnetic flux density.

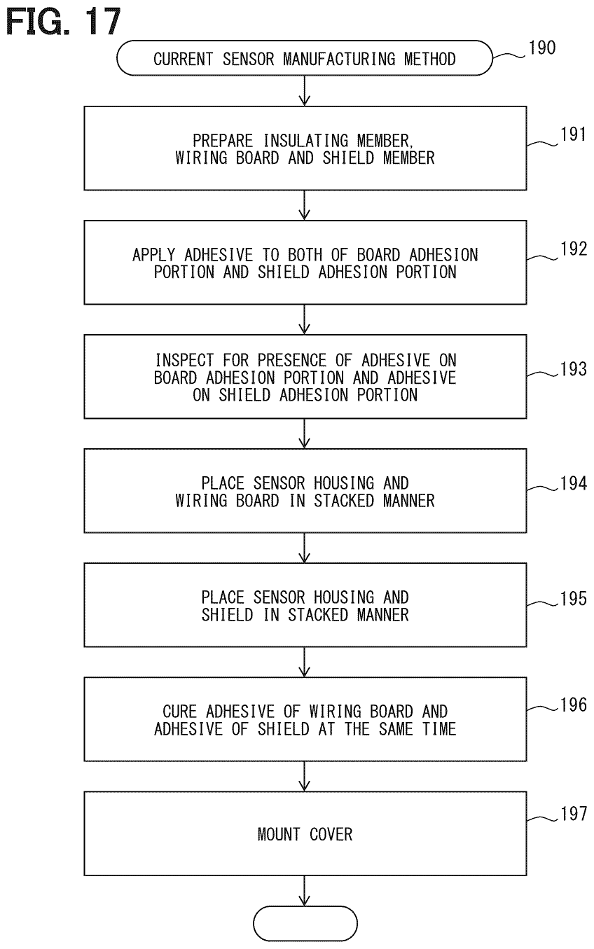

FIG. 17 is a process diagram showing the procedure of the method for manufacturing the current sensor 1. In particular, the procedure for an adhering step is shown in detail. A manufacturing method 190 of the current sensor 1 is also referred to as an assembly process for assembling the current sensor 1.

The manufacturing method includes step 191 as a preparation process. In step 191, a number of parts are provided. In step 191, the insulating member 20 including the sensor housing 21 and the cover 22 is prepared. The insulating member 20 includes the conductive member 10. The conductive member 10 may be provided in a state where it is insert-molded into the sensor housing 21. In the preparation process, the sensor housing 21 holding the conductive member 10 for allowing the current to flow is prepared. The sensor housing 21 includes the plurality of board contact portions 26a, the plurality of board adhesion portions 26b, the plurality of shield contact portions 27a, and the plurality of shield adhesion portions 27b.

In step 191, the wiring board 41 is prepared. The sensor element 42 provided as an IC package is mounted on the wiring board 41. The wiring board 41 includes circuit elements other than the sensor element 42. The wiring board 41 is provided in the state in which the plurality of these circuit elements are mounted thereon. In the preparation process, the wiring board 41 having the sensor element 42 for detecting the magnetic flux caused by the current mounted thereon.

In step 191, the shield member 50 is provided. At least the shield 51 is provided as a separate piece. The shield 52 may also be provided as a separate piece. The shield 52 may be provided in a state where it is insert molded in the sensor housing 21. Additionally, in step 191, the adhesive 30 is prepared. The adhesive 30 is in a fluid state before being cured. In the preparation process, the shield 51 is prepared as the magnetic shield member.

The manufacturing method includes step 192 as an application process. In step 192, the adhesive 30 is applied to the sensor housing 21. The adhesive 30 is a material that is in a fluid state at an initial temperature that is higher than the assumed temperature range of the current sensor 1 for use, and that hardens in the assumed temperature range of use. The adhesive 30 is a silicone-based adhesive. The adhesive 30 can be applied in a fluid state to the sensor housing 21 by various methods, such as coating or dropping. The adhesive 30 is applied to the top surfaces of the board adhesion portions 26b and the top surfaces of the shield adhesion portions 27b.

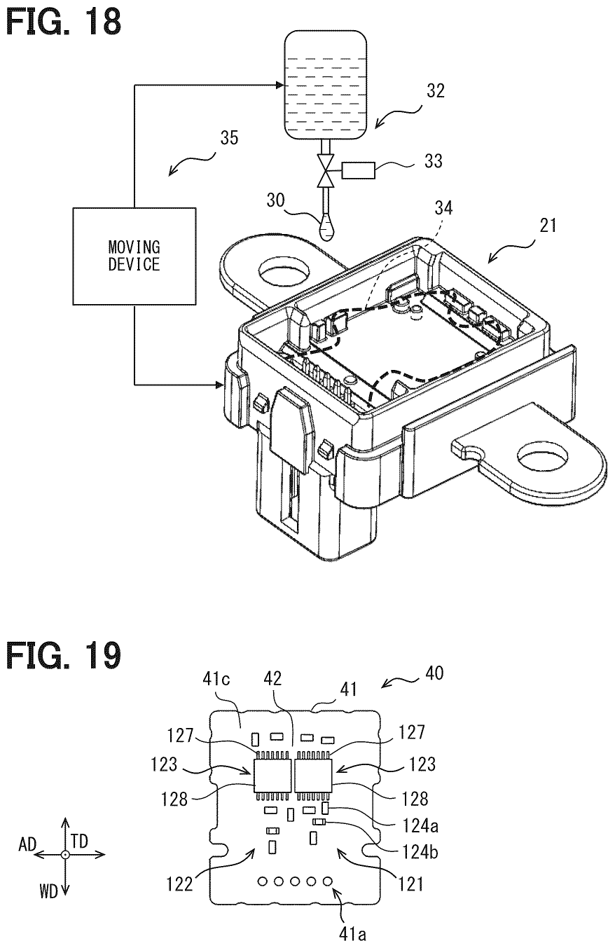

FIG. 18 is a block diagram of an application device in the application process. In the application process, the adhesive 30 in a fluid state is dropped from a dispenser 32. The adhesive 30 is dropped onto the top surface of the board adhesion portion 26b of the sensor housing 21 and onto the top surface of the shield adhesion portion 27b. The dispenser 32 may include an operable valve 33 for turning on and off the flow, i.e., the dripping, of the adhesive 30. The dropping position of the adhesive 30 is adjusted by relatively moving the dispenser 32 and/or the sensor housing 21.

The dropping positions are set on the top surfaces of the plurality of board adhesion portions 26b and the top surfaces of the plurality of shield adhesion portions 27b. The relative positional relationship between the dispenser 32 and the sensor housing 21 can be adjusted by a moving device 35. The moving device 35 can be provided by a variety of devices, such as an XY table, a robot, or the like. The moving device 35 moves the position of the dispenser 32 and/or the sensor housing 21 so that the dropping position passes through the top surfaces of the plurality of board adhesion portions 26b and the top surfaces of the plurality of shield adhesion portions 27b in order. The moving device 35 can be configured to move, for example, a nozzle from which the adhesive 30 exits.

The top surfaces of the plurality of board adhesion portions 26b and the top surfaces of the plurality of shield adhesion portions 27b are distributed in a loop shape on the outside of the container chamber 23. The plurality of dropping positions are set along a path 34 that is set to pass through these top surfaces in order. The path 34 is set so as to travel around all of the plurality of top surfaces in a single stroke.

The application process is performed before a board placement process and a shield placement process. In the application process, the adhesive 30 is applied to the plurality of top surfaces through the path 34 that travels in a single stroke around the wiring board 41 and the container chamber 23 that houses the shield 51. The plurality of board adhesion portions 26b and the plurality of shield adhesion portions 27b are arranged in a loop shape in the outer region of the container chamber 23. Furthermore, the path 34 for applying the adhesive 30 runs as a loop around the outer region. The application process is performed by moving the relative position of the nozzle that drops the adhesive onto the top surfaces and the sensor housing 21 having the container chamber 23 along the path 34. This allows the application process to be carried out at high speed.

The application process is performed so as to apply the adhesive 30 to the top surfaces of the plurality of board adhesion portions 26b and the top surfaces of the plurality of shield adhesion portions 27b. The application process is performed so as not to apply the adhesive 30 to the top surfaces of the plurality of board contact portions 26a and the top surfaces of the plurality of shield contact portions 27a. This provides the accurate positioning by the board contact portions 26a and the shield contact portions 27a, and the reliable adhesion at the plurality of board adhesion portions 26b and the plurality of shield adhesion portions 27b.

Returning to FIG. 17, the manufacturing method includes step 193 as an inspection process. In step 193, it is inspected whether or not the adhesive 30 has been applied to all of the top surfaces of the plurality of board adhesion portions 26b and the top surfaces of the plurality of shield adhesion portions 27b. The inspection process in step 193 can be performed by visual inspection by an operator. The inspection process in step 193 can be performed automatically by an image recognition device. In either case, intermediate products that have passed the inspection process are supplied to the subsequent process.

The inspection process is performed after the application process and before the board placement process and the shield placement process, which will be described later. In the inspection process, it is inspected that the adhesive 30 has been applied to the top surfaces of the plurality of board adhesion portions 26b and the top surfaces of the plurality of shield adhesion portions 27b. Furthermore, in the inspection process, it is inspected that the adhesive 30 has not been applied to the top surfaces of the plurality of board contact portions 26a and the top surfaces of the plurality of shield contact portions 27a. As such, accurate positioning and secure adhesion are ensured.

The manufacturing method includes step 194 as the board placement process. In step 194, the wiring board 41 is placed on the sensor housing 21. At this time, the wiring board 41 is guided to a specified position by the engagement between the protrusion 28a and the notch 41b. The engagement between the protrusion 28a and the notch 41b restricts the wiring board 41 from being erroneously assembled in a 180 degrees rotated manner.

In the process of placing the wiring board 41 to a specified position, the adhesive 30 applied to the top surfaces of the plurality of board adhesion portions 26b before curing is compressed and deformed. The deformation of the adhesive 30 allows the wiring board 41 to come into contact with the top surfaces of the plurality of board contact portions 26a. As a result, the wiring board 41 is positioned at the specified position.

In the board placement process, the wiring board 41 is brought into contact with the board contact portions 26a. As a result, the wiring board 41 is placed in the specified position. At this time, even if a small amount of adhesive 30 adheres to or penetrates the top surfaces of the plurality of board contact portions 26a, the adhesive 30 is pushed out. This provides a substantial contact state. Furthermore, in the board placement process, the wiring board 41 is brought into contact with the adhesive 30 applied to the top surfaces of the board adhesion portions 26b, thereby deforming the adhesive 30 between the top surfaces and the wiring board 41. The deformed adhesive 30 has a shape similar to that of the cured adhesive layer 31.

The manufacturing method includes step 195 as the shield placement process. In step 195, the shield 51 is placed on the sensor housing 21. The placement of the shield 51 is performed without allowing the adhesive 30 to cure. At this time, the shield 51 is guided to a specified position by the engagement of the protrusions 28a and 28b with the notches 51b at the four corners of the shield 51. Furthermore, the engagement of the protrusions 28a and 28b with the notches 51b at the four corners of the shield 51 restrict erroneous assembly in which the shield 51 is rotated 90 degrees.

In the process of placing the shield 51 to the specified position, the adhesive 30 applied to the top surfaces of the plurality of shield adhesion portions 27b before curing is compressed and deformed. The deformation of the adhesive 30 allows the shield 51 to come into contact with the top surfaces of the plurality of shield contact portions 27a. As a result, the shield 51 is positioned at the specified position. The shield 51 is disposed above the wiring board 41 in a layered manner.

In the shield arrangement process, the shield 51 is brought into contact with the plurality of shield contact portions 27a. As a result, the shield 51 is placed in the specified position. At this time, even if a small amount of adhesive 30 is adhered to or penetrates to the top surfaces of the plurality of shield contact portions 27a, the adhesive 30 is pushed out. This provides a substantial contact state. Furthermore, in the shield placement process, the adhesive 30 applied to the top surfaces of the plurality of shield adhesion portions 27b is deformed between the top surfaces and the shield 51. The deformed adhesive 30 has a shape similar to that of the cured adhesive layer 31.

The manufacturing method includes step 196 as a curing process. In step 196, both the adhesive 30 for adhering the wiring board 41 and the adhesive 30 for adhering the shield 51 are cured at the same time. By this process, a plurality of adhesive layers 31 are formed between the top surfaces of the plurality of board adhesion portions 26b and the wiring board 41. At the same time, by this process, a plurality of adhesive layers 31 are formed between the top surfaces of the plurality of shield adhesion portions 27b and the shield 51.

In the present embodiment, the curing process is performed by lowering the temperature of the adhesive 30 having a fluidity to harden the adhesive 30, i.e., to cause the adhesive 30 to lose its fluidity. In this case, the temperature of the adhesive 30 is gradually reduced after the application process. Therefore, the board placement process and the shield placement process are performed while the adhesive 30 has the fluidity. This allows the adhesive 30 to deform so as to allow the wiring board 41 and the shield 51 to be positioned to the specified positions. Alternatively, an adhesive 30 that hardens when the temperature increases may be used. In this case, the temperature of the adhesive 30 having the fluidity in the application process is increased to a curing temperature in the curing process. The adhesive 30 is deformed in the board placement process and the shield placement process, and is changed into the adhesive layer 31 in the curing process.

The curing process is performed after the board placement process and the shield placement process. In the curing process, both the adhesive 30 positioned between the board adhesion portions 26b and the wiring board 41 and the adhesive 30 positioned between the shield adhesion portions 27b and the shield 51 are cured simultaneously. In this manufacturing method, the curing process forms the adhesive layers 31 that adhere the board adhesion portions 26b and the wiring board 41 by curing the adhesive 30 in the deformed shape. At the same time, the curing process forms the adhesive layers 31 that adhere the shield adhesion portions 27b and the shield 51 by curing the adhesive 30 in the deformed shape. In this manufacturing method, the adhesive 30 is maintained in a fluid state throughout the period from the board placement process to the shield placement process. Moreover, the board placement process and the shield placement process are carried out successively In this manufacturing method, the adhesive 30 loses its fluidity during the curing process. After the curing process, the adhesive 30 changes into the adhesive layer 31 that have lost its fluidity.

The manufacturing method includes step 197 as a mounting process. In step 197, the cover 22 is mounted to the sensor housing 21. In the mounting process, the sensor housing 21 and the cover 22 are connected by the plurality of coupling mechanisms 24. During the mounting process, the engagement arm 24a is operated in the thickness direction TD along the groove 24d. The engagement arm 24a is guided in the thickness direction TD along the groove 24d. As a result, the engagement arm 24a can be operated so as to be stably and reliably connected to the engagement claw 24b. The same effects of stability and reliability can also be obtained in the coupling mechanisms 24 at the same time. Therefore, the configuration having the plurality of connecting mechanisms 24 provides a significant effect. Furthermore, the engagement arm 24a connected to the engagement claw 24b is at least partially housed within the groove 24d. As a result, it is possible to suppress an erroneous operation that would cause the engagement arm 24a to be deformed again.

The mounting process is also referred to as a cover mounting process. The cover mounting process can be performed after the curing process or before the curing process. In the cover mounting process, the cover 22 is connected to the sensor housing 21 to close the container chamber 23. The sensor housing 21 includes the plurality of board contact portions 26a, the plurality of board adhesion portions 26b, the plurality of shield contact portions 27a, and the plurality of shield adhesion portions 27b. In the cover mounting process, the shield pressing portions 22e provided on the cover 22 are brought into contact with the shield 51. This allows the position of the shield 51 to be fixedly maintained between the sensor housing 21 and the cover 22. For example, even if peeling or cracking occurs in the adhesive layer 31, the position of the shield 51 is stably maintained.

The present disclosure provides a method for manufacturing a current sensor. In the method for manufacturing the current sensor 1, the wiring board 41 is brought into contact with the adhesive 30 applied to the top surfaces of the plurality of board adhesion portions 26b. This causes the adhesive 30 between the top surfaces and the wiring board 41 to deform. As a result, the wiring board 41 is positioned at a specified position. Moreover, the adhesive 30 can be deformed into a shape suitable for the specified position. In the method for manufacturing the current sensor 1, the shield 51 is brought into contact with the adhesive 30 applied to the top surfaces of the plurality of shield adhesion portions 27b. This causes the adhesive 30 to deform between the top surfaces and the shield 51. As a result, the shield 51 is positioned at a specified position. Moreover, the adhesive 30 can be deformed into a shape suitable for the specified position. In the curing process, the adhesive 30 is cured simultaneously after the board placement process and the shield placement process. In the curing process, both the adhesive 30 positioned between the board adhesion portions 26b and the wiring board 41 and the adhesive 30 positioned between the shield adhesion portions 27b and the shield 51 are cured at the same time. As a result, a high degree of productivity suitable for mass production is realized.

### Second Embodiment

The present embodiment is a modified example based on the preceding embodiment. In the embodiment described above, the through holes 11d and 11e have equal diameters. Instead, in the present embodiment, the through holes 211d, 211e have different diameters.

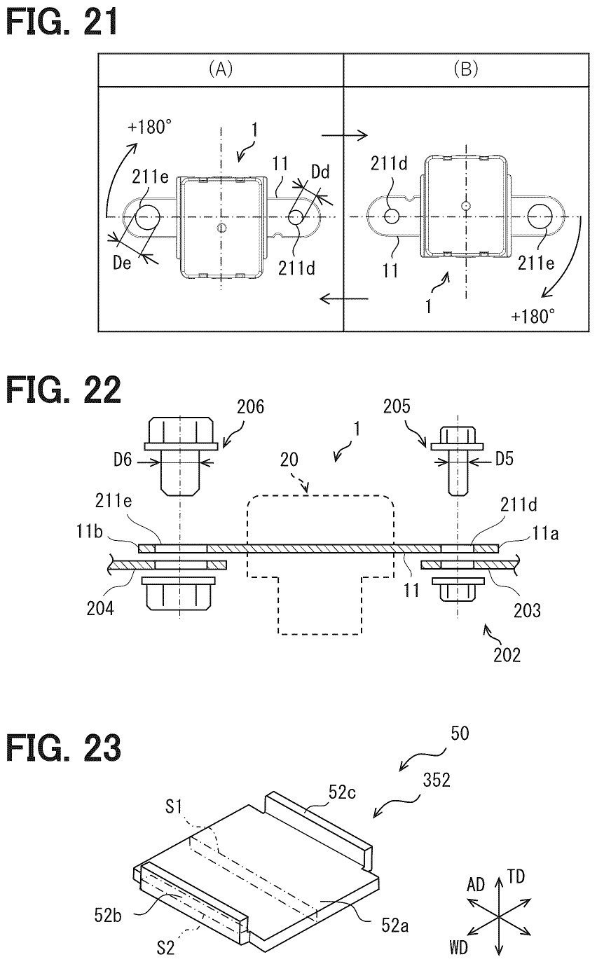

In FIG. 21, the current sensor 1 has a first through hole 211d and a second through hole 211e. A first diameter Dd of the first through hole 211d and a second diameter De of the second through hole 211e are different. The first diameter Dd of the first through hole 211d is smaller than the second diameter De of the second through hole 211e (Dd<De).

Assume that the current sensor 1 has an orientation (A) of FIG. 21 and an orientation (B) in FIG. 21. The orientation of the current sensor 1 is inverted by 180 degrees in the plan view between the orientation (A) and the orientation (B). The orientation (A) is, for example, a normal orientation. The orientation (B) is, for example, an incorrect inverted orientation.

The current sensor 1 has a similar appearance between the orientation (A) and the orientation (B). However, the first diameter Dd of the first through hole 211d and the second diameter De of the second through hole 211e indicate a clear difference in orientation. A user of the current sensor 1 can easily and reliably visually recognize the orientation of the current sensor 1 based on the diameter Dd of the first through hole 211d and the second diameter De of the second through hole 211e. The user includes a worker who installs the current sensor 1 in a device in which the current sensor 1 is used. By recognizing the orientation of the current sensor 1, the user can suppress the current sensor 1 from being installed in an incorrect, inverted orientation.

FIG. 22 shows an exploded view of a connection structure between the current sensor 1 and a device 202 to which the current sensor 1 is applied. In FIG. 22, the conductor member 11 is shown in a cross-section. In FIG. 22, the main body of the current sensor 1 including the insulating member 20 is omitted and indicated by a dashed line. The device 202 is a battery control device, a current sensor assembly, or a power conversion device that includes the current sensor 1. The device 202 includes conductive members 203, 204 through which a current to be detected flows. The conductive member 203 and the conductive member 204 are electrically connected by the conductor member 11. The conductive member 203 has a through hole having an inner diameter equal to that of the through hole 211d at a position to be able to communicate with the through hole 211e in the axial direction. The conductive member 203 and the one end 11a are connected by a first connecting member 205. The conductive member 204 has a through hole having an inner diameter equal to that of the through hole 211e at a position to be able to communicate with the through hole 211e in the axial direction. The conductive member 204 and the other end 11b are connected by a second connecting member 206. As such, the current to be detected can flow.

The connecting members 205 and 206 are provided by bolts and nuts. The bolts and nuts may have opposite relationship in the vertical direction from the arrangement shown in the figure. The bolts or nuts may be fixed to the conductive members 203 and 204 or to the conductor member 11. The nominal diameter of the bolt and the nut that provide the first connecting member 205 is different from the nominal diameter of the bolt and the nut that provide the second connecting member 206. The nominal diameter of the bolt and the nut that provide the first connecting member 205 and the nominal diameter of the bolt and the nut that provide the second connecting member 206 are different enough to suppress incorrect combination of the bolts and nuts. For example, when the bolt providing the first connecting member 205 and the nut providing the second connecting member 206 are combined, although they can be inserted, since the threads do not mesh, no tightening force is generated. For example, when the bolt providing the second connecting member 206 is combined with the nut providing the first connecting member 205, no tightening force is generated since insertion is not possible. The difference between the nominal diameter of the bolt and the nut that provide the first connecting member 205 and the nominal diameter of the bolt and the nut that provide the second connecting member 206 is such that no tightening force is generated.

The connecting members 205 and 206 have shaft portions that are inserted into the through holes 211d and 211e. The shaft of the connecting member 205 has a third diameter D5. The third diameter D5 of the shaft of the connecting member 205 fits into the through hole 211d. The third diameter D5 is smaller than the first diameter Dd (D5<Dd). The third diameter D5 is smaller than the second diameter De (D5<De). The shaft of the connecting member 206 has a fourth diameter D6. The fourth diameter D6 of the shaft of the connecting member 206 fits into the through hole 211e. The fourth diameter D6 is greater than the first diameter Dd (D6>Dd). The fourth diameter D6 is smaller than the second diameter De (D6<De). The third diameter D5 and the fourth diameter D6 are different. The third diameter D5 is smaller than the fourth diameter D6 (D5<D6). The difference between the third diameter D5 and the fourth diameter D6 is a difference that suppresses the shaft portion of the second connecting member 206 from being inserted into the first through-hole 211d. In other words, the difference between the third diameter D5 and the fourth diameter D6 is a difference that structurally prohibits the use of the second connecting member 206 in the first through hole 211d.

The connecting member 205 can be used for both the through holes 211d and 211e. However, when the connecting member 205 is used in the through hole 211e, an appropriate radial clearance cannot be obtained. The connecting member 206 can only be used with the through hole 211e. The connecting member 206 cannot be inserted into the through hole 211d and therefore cannot be used with the through hole 211d. The current sensor 1 can be fixed using the connecting members 203 and 204 only in the normal orientation (A). The current sensor 1 cannot be fixed using the connecting members 203, and 204 in the incorrect inverted orientation (B). As a result, it is possible to suppress the current sensor 1 from being assembled in an erroneous inverted position. Moreover, in addition to visual inspection by the user, the above situation can be suppressed structurally.

### Third Embodiment

The present embodiment is a modified example based on the preceding embodiment. In the embodiment described above, at least one or both of the shield 51 and the shield 52 are provided by a stack of steel plates. Alternatively, at least one or both of shields 51 and 52 may be provided by a continuous block of magnetic material.

In FIG. 23, the shield 352 is provided by a single steel plate. The shield 352 is formed from a material that is continuous in the entire shield 352. The shield 352 is a member that can be referred to as a single steel plate. The shield 352 provides a magnetic path for the normal magnetic flux induced by the current flowing through the conductive member 10. The shield 352 has an easy axis of magnetization aligned with the direction of the normal magnetic flux. The shield 352 has a central portion 52a. The central portion 52a is in the shape of a quadrilateral plate. The central portion 52a extends parallel to the conductive member 10. The central portion 52a has a magnetic path cross section perpendicular to the normal magnetic flux. The shield 352 has two extension portions 52b and 52c extending from the central portion 52a toward the shield 51. The extension portions 52b and 52c extend from both ends of the central portion 52a on the axis of easy magnetization. The extensions 52b and 52c have a magnetic path cross section perpendicular to the normal magnetic flux. The shield 352 is formed so that a magnetic path cross-sectional area S1 at the central portion 52a is larger than a magnetic path cross-sectional area S2 at the extension portions 52b and 52c. The central portion 52a may also be referred to as a first portion. The extensions 52b and 52c can also be referred to as second portions. Also in the present embodiment, the shield 352 may provide the magnetic shield similar to the shield 52 in the preceding embodiment.

### Other Embodiments

The disclosure in this specification and drawings is not limited to the illustrated embodiments. The disclosure encompasses the illustrated embodiments and variations thereon by those skilled in the art. For example, the disclosure is not limited to the combination of parts and/or elements illustrated in the embodiments. The disclosure can be implemented in various combinations. The disclosure may have additional portions that can be added to the embodiments. The disclosure encompasses embodiments in which parts and/or elements are omitted. The disclosure encompasses any replacements or combinations of parts and/or elements between one embodiment and the other embodiments. The scope of the disclosed technology is not limited to the description of the embodiments. Some of the technical scopes disclosed herein are defined by the claims, and should be interpreted as including all modifications within the scope and meaning equivalent to the claims.

The disclosure in the specification, drawings, and the like is not limited by the claims. The disclosure in the specification, the drawings, and the like encompasses the technical ideas described in the claims, and extends to technical ideas that are more diverse and extensive than the technical ideas described in the claims. Therefore, various technical ideas can be extracted from the disclosure of the specification, the drawings, and the like without being bound by the claims.

In the embodiment(s) described above, the engagement arm 24a, which provides the coupling mechanism 24, is provided on the cover 22, and the engagement claw 24b, which provides the coupling mechanism 24, is provided on the sensor housing 21. This arrangement can be referred to as a normal arrangement. Alternatively, the engagement arm 24a and the engagement claw 24b may be arranged in reverse. For example, the engagement arm 24a can be provided on the sensor housing 21. In this case, the engagement claw 24b is provided on the cover 22. This arrangement can be referred to as an inverted arrangement. Furthermore, among the plurality of coupling mechanisms 24, some may have the normal arrangement and the remaining may have the reverse arrangement.

In the embodiment(s) described above, the adhesive 30 is the material that is in the fluid state at an initial temperature that is higher than the assumed temperature range of use of the current sensor 1, and that hardens in the assumed temperature range of use. Alternatively, the adhesive 30 may be a material that is in a fluid state at room temperature and hardens at a hardening temperature that is higher than room temperature. The adhesive 30 is not limited to a thermosetting material such as a high-temperature curing material or a low-temperature curing material, and various other materials can be used. The adhesive 30 may be provided, for example, by a two-part adhesive that hardens after the two parts are mixed.

In the embodiment(s) described above, the shield member 50 has two magnetic gaps between the shield 51 and the shield 52. Alternatively, the shield member 50 may have a single magnetic gap. Furthermore, the shield member 50 may have three or more magnetic gaps. In the embodiment described above, the conductive member 10, the sensor element 42, and the shield member 50 are arranged and shaped symmetrically with respect to the line of symmetry SY. Alternatively, the shield member 50 may have a point-symmetrical arrangement and shape with respect to the sensor element 42. The arrangement and shape of the shield member 50 can be designed to bring the current detection accuracy closer to a required level.

In the embodiment(s) described above, the shield 51 and the shield 52 that provide the shield member 50 are provided by the plurality of steel plates stacked along the thickness direction TD. Alternatively, at least one or both of the shield 51 and the shield 52 may be provided by a plurality of steel plates stacked along the axial direction AD. In this case, the number M of the steel plates in the portion 52a is equal to the number N of the steel plates in the portions 52b and 52c (M=N). Furthermore, in the embodiment(s) described above, the number M of the steel plates in the portion 52a is greater than the number N of the steel plates in the portions 52b and 52c (M>N). Alternatively, the number M of the steel plates in the portion 52a may be smaller than or equal to the number N of the steel plates in the portions 52b and 52c (M<N, or M=N). Furthermore, in the embodiment(s) described above, the number P of the first steel plates is greater than the number Q of the second steel plates (P>Q). Alternatively, the number P of the first steel plates may be equal to the number Q of the second steel plates. Furthermore, the number P of the first steel plates may be smaller than the number Q of the second steel plates.

### Disclosure of Technical Ideas

This specification discloses several technical ideas described in the several items listed below. Some items may be written in a multiple dependent form in which a subsequent item refers to the preceding items as an alternative form. In addition, some items may be written in a multiple dependent form referring to another multiple dependent form items. These items written in a multiple dependent form define multiple technical ideas.

### Technical Idea 1

A method for manufacturing a current sensor, includes: preparing a sensor housing (21), a wiring board (41), and a shield (51); placing the wiring board; placing the shield; and curing adhesive (30). In the preparing, the sensor housing prepared holds a conductive member that allows an electric current to flow therein and has a plurality of board contact portions, a plurality of board adhesion portions, a plurality of shield contact portions, and a plurality of shield adhesion portions. The wiring board prepared has a sensor element mounted thereon that detects a magnetic flux caused by the electric current. The shield prepared is a magnetic shield member. In the placing of the wiring board, the wiring board is brought into contact with the plurality of board contact portions so that the wiring board is placed in a specified position and is brought into contact with an adhesive applied on a plurality of top surfaces of the board adhesion portions so that the adhesive is deformed between the top surfaces and the wiring board. In the placing of the shield, the shield is brought into contact with the plurality of shield contact portions so that the shield is placed in a specified position while deforming an adhesive applied on a plurality of top surfaces of the shield adhesion portions between the top surfaces and the shield. The curing is performed after the placing of the wiring board and the placing of the shield. In the curing, both the adhesive positioned between the board adhesion portions and the wiring board and the adhesive positioned between the shield adhesion portions and the shield are cured simultaneously.

### Technical Idea 2

In the method for manufacturing a current sensor as in Technical Idea 1, the adhesives maintains its fluidity in a period from the placing of the wiring board to the placing of the shield. The placing of the wiring board and the placing of the shield are performed successively, and the adhesives lose its fluidity in the curing.

### Technical Idea 3

In the method for manufacturing a current sensor as in Technical Idea 1 or 2, in the curing, an adhesive layer that adheres the board adhesion portions and the wiring board to each other is formed by curing the adhesive between the board adhesion portions and the wiring board in a deformed shape. At the same time, an adhesive layer that adheres the shield adhesion portions and the shield is formed by curing the adhesive between the shield adhesion portions and the shield in a deformed state.

### Technical Idea 4

The method for manufacturing a current sensor as in any one of Technical Ideas 1 to 3, further includes applying the adhesive, before the placing of the wiring board and the placing of the shield. In the applying, the adhesive is applied onto the top surfaces of the board adhesion portions and the top surfaces of the shield adhesion portions along a path (34) that goes around a container chamber (23) of the sensor housing that houses the wiring board and the shield in a single stroke.

### Technical Idea 5

In the method for manufacturing a current sensor as in Technical Idea 4, the plurality of the board adhesion portions and the plurality of the shield adhesion portions are disposed along a loop shape in an outer region of the container chamber, and the path runs along the loop shape in the outer region.

### Technical Idea 6

In the method for manufacturing a current sensor as in Technical Idea 4 or 5, the applying is performed by moving a relative position between a nozzle that drips the adhesive onto the top surfaces and the sensor housing having the container chamber along the path.

### Technical Idea 7

In the method for manufacturing a current sensor as in any one of Technical Ideas 4 to 6, the applying is performed by applying the adhesive onto the top surfaces of the plurality of board adhesion portions and the top surfaces of the plurality of shield adhesion portions, without applying the adhesive onto the top surfaces of the plurality of board contact portions and the top surfaces of the plurality of shield contact portions.

### Technical Idea 8

The method for manufacturing a current sensor as in any one of Technical Ideas 4 to 7, further includes inspecting, after the applying and before the placing of the wiring board and the placing of the shield. In the inspecting, it is inspected that the adhesive has been applied onto the top surfaces of the plurality of board adhesion portions and the top surfaces of the plurality of shield adhesion portions, and that the adhesive has not not applied onto the top surfaces of the plurality of board contact portions and the top surfaces of the plurality of shield contact portions.

### Technical Idea 9

The method for manufacturing a current sensor as in any one of Technical Ideas 4 to 8, further includes mounting a cover (22) by coupling the cover to the sensor housing, which has the plurality of the board contact portions, the plurality of the board adhesion portions, the plurality of the shield contact portions, and the plurality of the shield adhesion portions, thereby to close the container chamber, after the curing or before the curing.

### Technical Idea 10

In the method for manufacturing a current sensor as in Technical Idea 9, the mounting of the cover includes bringing a shield pressing portion (22e) of the cover into contact with the shield.

### Disclosure of Other Technical Ideas

Furthermore, this specification discloses several technical ideas described in several items listed below. These technical ideas are to provide a current sensor that suppresses magnetic saturation in a shield member and has high detection accuracy.

### Technical Idea 11

A current sensor includes: a conductive member (10) that allows an electric current to flow therein; a sensor element (42) that is disposed away from the conductive member and detects a magnetic flux resulting from the electric current; and a magnetic shield member (50) that is disposed at least partially around the conductive member and the sensor element and defines a magnetic gap (G50). The shield member has, in a magnetic path formed by the shield member, a first portion (52a) away from the gap and a second portion (52b, 52c) closer to the gap than the first portion. The shield member is configured such that, with respect to a magnetic path cross-sectional area of the magnetic path, the first portion has a magnetic path cross-sectional area (S1) larger than a magnetic path cross-sectional area (S2) of the second portion (S1>S2).

### Technical Idea 12

In the current sensor as in Technical Idea 11, the shield member is provided by a stack of steel plates or a block of a single steel plate.

### Technical Idea 13

In the current sensor as in Technical Idea 11 or 12, the shield member (50) includes a first shield (51) and a second shield (52, 352) arranged to interpose the conductive member and the sensor element therebetween. The first shield has a quadrilateral shape. The second shield has a central portion (52a) having a quadrilateral shape, a first extension portion (52b) extending from one end of the central portion toward the first shield and opposing the first shield to define the gap, and a second extension portion (52c) extending from the other end of the central portion toward the first shield and opposing the first shield to define the gap. The central portion provides the first portion, and the first extension portion or the second extension portion provides the second portion.

### Technical Idea 14

In the current sensor as in any one of Technical Ideas 11 to 13, the first portion includes a portion that is farthest from the gap.

### Technical Idea 15

A current sensor includes: a conductive member (10) that allows an electric current to flow therein; a sensor element (42) that is disposed away from the conductive member and detects a magnetic flux resulting from the electric current; and a magnetic shield member (50) that is disposed at least partially around the conductive member and the sensor element and defines a magnetic gap (G50). The shield member is provided by a stack of steel plates. The shield member has, in a magnetic path formed by the shield member, a first portion (52a) away from the gap and a second portion (52b, 52c) closer to the gap than the first portion. The shield member is configured so that the number (M) of the stacked steel plates in the first portion is greater than the number (N) of the stacked steel plates in the second portion (M>N).

### Technical Idea 16

In the current sensor as in Technical Idea 15, the shield member (50) includes a first shield (51) and a second shield (52, 352) disposed to interpose the conductive member and the sensor element therebetween. The first shield has a quadrilateral shape. The second shield has a central portion (52a) having a quadrilateral shape, a first extension portion (52b) extending from one end of the central portion toward the first shield and opposing the first shield to define the gap, and a second extension portion (52c) extending from the other end of the central portion toward the first shield and opposing the first shield to define the gap. The central portion provides the first portion, and the first extension portion or the second extension portion provides the second portion.

### Technical Idea 17

In the current sensor as in Technical Idea 15 or 16, the second shield has a first steel plate (52g1, 52g2, 52g3, 52g4) having the central portion, and the first extension portion and the second extension portion, and a second steel plate (52g5) having only the central portion. The first steel plate and the second steel plate are disposed in a stacked manner in the central portion.

### Technical Idea 18

In the current sensor as in Technical Idea 17, the number (P) of the first steel plate is greater than the number (Q) of the second steel plate.

### Technical Idea 19

In the current sensor as in Technical Idea 17 or 18, the second steel plate is disposed on the opposite side to the direction in which the first extension portion and the second extension portion extend.

### Technical Idea 20

In the current sensor as in Technical Idea 13 r 16, the second shield has a plurality of first steel plates (52g1, 52g2, 52g3, 52g4) having the central portion, the first extension portion, and the second extension portion, and a second steel plate (52g5) having only the central portion and the number (Q) of which is less than the number (P) of the plurality of first steel plates. The plurality of first steel plates are disposed in a stacked manner at the central portion, the first extension portion, and the second extension portion, respectively, and the plurality of first steel plates and the second steel plate are disposed in a stacked manner at the central portion.

### Technical Idea 21

In the current sensor as in any one of Technical Ideas 15 to 20, the first portion includes a portion farthest from the gap.

Furthermore, this specification discloses several technical ideas described in several items listed below. The purpose of these technical ideas is to provide a current sensor in which detection accuracy is maintained by suppressing misalignment of the shield 51 even if the adhesion between the shield 51 and the sensor housing 21 by the adhesive layer 31 becomes unstable. For example, a decrease in detection accuracy may appear as a change in magnetic flux distribution caused by the misalignment of the shield 51 and an associated change in the detection value.

### Technical Idea 22

A current sensor includes: a conductive member (10) that allows an electric current to flow therein; a sensor element (42) that detects a magnetic flux resulting from the electric current; a shield (51) as a magnetic shield member; an insulating member (20) that includes a sensor housing (21) for positioning the conductive member, the sensor element, and the shield in a layered manner and a cover (22) connected to the sensor housing; and an adhesive layer (31) that adheres the shield to the sensor housing on one surface of the shield. The cover is in contact with the other surface of the shield and includes a shield pressing portion (22e) for supporting the shield.

### Technical Idea 23

In the current sensor as in Technical Idea 22, the cover includes a plurality of the shield pressing portions (22e).

### Technical Idea 24

In the current sensor as in Technical Idea 23, the plurality of shield pressing portions (22e) are disposed in a dispersed manner along the edge of the shield.

### Technical Idea 25

In the current sensor as in any one of Technical Ideas 22 to 24, the sensor housing has a shield adhesion portion (27b) that is adhered to the shield via the adhesive layer.

### Technical Idea 26

In the current sensor as in any one of Technical Ideas 22 to 25, the sensor housing has a shield contact portion (27a) that is in contact with the one surface of the shield in a specific range without the adhesive layer, and the shield pressing portion is in contact with the other surface of the shield in the specific range.

Furthermore, this specification discloses several technical ideas described in several items listed below. The purpose of the technical idea is to provide an insulating member that can stably maintain the connection state between the sensor housing 21 and the cover 22. The technical idea can be used as a current sensor. The purpose of the technical idea is to provide a current sensor that maintains detection accuracy by stably maintaining a connected state. For example, a decrease in detection accuracy may occur when the connection between the sensor housing 21 and the cover 22 is unintentionally released.

### Technical Idea 27

An insulating member includes a sensor housing (21) made of an insulating material, and a cover (22) made of an insulating material and is connected to the sensor housing to define a container chamber (23) between the sensor housing and the cover. The insulating member includes: an elastically deformable engagement arm (24a) that protrudes from one of the sensor housing and the cover; a side wall surface (24c) that is provided on the other of the sensor housing and the cover and defines a groove (24d) that receives the engagement arm; and an engagement claw (24b) that is provided on the other of the sensor housing and the cover and engages with the engagement arm positioned in the groove.

### Technical Idea 28

In the insulating member as in Technical Idea 27, the groove positions the engagement arm so that it is recessed from the side wall surface.

### Technical Idea 29

In the insulating member as in Technical Idea 27 or 28, the engagement arm has two elastic arms (24f) extending in parallel and an engagement claw (24e) arranged to connect the tip portions of the two elastic arms and engaging with the engagement claw, and the engagement claw is defined by protruding a portion of the groove.

### Technical Idea 30

In the insulating member as in any one of Technical Ideas 27 to 29, the sensor housing and the cover arrange a conductive member (10) that allows an electric current to flow therein, a wiring board (41) that has a sensor element (42) for a detecting magnetic flux caused by the electric current mounted thereon, and a shield (51) as a magnetic shield member, in a layered manner along a direction in which the engagement arm protrudes.

### Technical Idea 31

In the insulating member as in any one of Technical Ideas 27 to 30, a direction in which the engagement arm protrudes is referred to as a thickness direction (TD), a direction of the electric current flowing in the conductive member is referred to as an axial direction (AD), and a direction perpendicular to the thickness direction and the axial direction is referred to as a width direction (WD). The one of the sensor housing and the cover has a plurality of the engagement arms at both ends in the width direction, and the other of the sensor housing and the cover has the side wall surface and the engagement claw at both ends in the width direction.

Furthermore, this specification discloses several technical ideas described in several items listed below. The purpose of the technical idea is to define the normal position of the current sensor.

### Technical Idea 32

A current sensor includes: a conductive member (10) that allows an electric current to flow; a sensor element (42) that detects a magnetic flux resulting from the electric current flowing through the conductive member; a first through hole (211d) that is provided at one end of the conductive member and has a predetermined first diameter (Dd); and a second through hole (211e) that is provided at the other end of the conductive member and has a second diameter (De) different from the first diameter.

### Technical Idea 33

The current sensor as in Technical Idea 32 further includes: a first connecting member (205) that has a shaft portion with a third diameter (D5) insertable into the first through hole, and a second connecting member (206) that has a shaft portion with a fourth diameter (D6) insertable into the second through hole but not insertable into the first through hole.

### Technical Idea 34

In the current sensor as in Technical Idea 33, a difference between the third diameter and the fourth diameter is a difference that suppresses the shaft portion of the second connecting member from being inserted into the first through hole.

### Technical Idea 35

In the current sensor as in Technical Idea 33 or 34, the shaft portion is provided by a bolt.

### Technical Idea 36

In the current sensor as in Technical Idea 35, a difference between a nominal diameter of a bolt and a nut providing the first connecting member and a nominal diameter of a bolt and a nut providing the second connecting member has a degree that suppresses incorrect combination of the bolts and nuts.

What is claimed is:

1. A method for manufacturing a current sensor, the method comprising:
preparing a sensor housing, a wiring board, and a shield, the sensor housing holding a conductive member that allows an electric current to flow therein and having a plurality of board contact portions, a plurality of board adhesion portions, a plurality of shield contact portions, and a plurality of shield adhesion portions, the wiring board having a sensor element mounted thereon and detecting a magnetic flux caused by the electric current, the shield being a magnetic shield member;
placing the wiring board by bringing the wiring board into contact with the plurality of board contact portions so that the wiring board is placed in a specified position and bringing the wiring board into contact with an adhesive applied on a plurality of top surfaces of the board adhesion portions so that the adhesive is deformed between the top surfaces and the wiring board;
placing the shield by bringing the shield into contact with the plurality of shield contact portions so that the shield is placed in a specified position and deforming an adhesive applied on a plurality of top surfaces of the shield adhesion portions between the top surfaces and the shield; and
after the placing of the wiring board and the placing of the shield, curing both the adhesive positioned between the board adhesion portions and the wiring board and the adhesive positioned between the shield adhesion portions and the shield simultaneously.

2. The method according to claim 1, wherein
the adhesives maintain a fluidity during a period from the placing of the wiring board and the placing of the shield,
the placing of the wiring board and the placing of the shield are performed successively, and
the adhesives lose the fluidity in the curing.

3. The method according to claim 1, wherein
in the curing, the adhesive positioned between the board adhesion portions and the wiring board in a deformed shape and the adhesive positioned between the shield adhesion portions and the shield in a deformed shape are cured simultaneously, thereby forming an adhesive layer adhering the board adhesion portions and the wiring board and an adhesive layer adhering the shield adhesion portions and the shield.

4. The method according to claim 1, further comprising:
before the placing of the wiring board and the placing of the shield, applying the adhesives to the plurality of top surfaces of the board adhesion portions and the plurality of top surfaces of the shield adhesion portions along a path that goes around a container chamber that houses the wiring board and the shield in a single stroke.

5. The method according to claim 4, wherein
the plurality of board adhesion portions and the plurality of shield adhesion portions are disposed along a loop shape in an outer region of the container chamber, and the path runs along the loop shape in the outer region.

6. The method according to claim 5, wherein
in the applying, a relative position between a nozzle that drips the adhesive onto the plurality of top surfaces of the board adhesion portions and the shield adhesion portions and the sensor housing having the container chamber along the path.

7. The method according to claim 4, wherein
the applying is performed by applying the adhesive onto the plurality of top surfaces of the board adhesion portions and the plurality of top surfaces of the shield adhesion portions without applying the adhesive onto a plurality of top surfaces of the board contact portions and a plurality of top surfaces of the shield contact portions.

8. The method according to claim 4, further comprising:
after the applying and before the placing of the wiring board and the placing of the shield, inspecting that the adhesive has been applied onto the plurality of top surfaces of the board adhesion portions and the plurality of top surfaces of the shield adhesion portions, and that the adhesive has not been applied onto a plurality of top surfaces of the board contact portions and a plurality of top surfaces of the shield contact portions.

9. The method according to claim 4, further comprising:
after the curing or before the curing, mounting a cover by coupling the cover to the sensor housing that has the plurality of board contact portions, the plurality of board adhesion portions, the plurality of shield contact portions and the plurality of shield adhesion portions, thereby to close the container chamber.

10. The method according to claim 9, wherein
the mounting includes bringing a shield pressing portion provided on the cover into contact with the shield.
